(19) United States
(12) Patent Application Publication
(10) Pub. No.: US 2026/0130103 A1
(43) Pub. Date: May 7, 2026

(54) DISPLAY DEVICE, REPAIRING METHOD THEREOF AND ELECTRONIC DEVICE HAVING THE DISPLAY DEVICE

(71) Applicant: Samsung Display Co., LTD., Yongin-si (KR)

(72) Inventor: Jong Hyun CHOI, Yongin-si (KR)

(21) Appl. No.: 19/237,796

(22) Filed: Jun. 13, 2025

(30) Foreign Application Priority Data
Nov. 7, 2024 (KR) 10-2024-0157066

(51) Int. Cl. H10K 71/00; H10K 59/121; H10K 59/123; H10K 59/131; H10K 59/88

(52) U.S. Cl. CPC H10K 71/861; H10K 59/1213; H10K 59/1216; H10K 59/123; H10K 59/131; H10K 59/88

(57) ABSTRACT

A display device includes a substrate in which a display area including first and second areas and a non-display area surrounding at least one side of the display area are defined, a sub-pixel arranged in the display area, first and second dummy pixels arranged in the non-display area, and a repair line commonly provided to the display area and the non-display area and extending in a first direction. The non-display area includes a first non-display area and a second non-display area. The repair line includes a first repair line and a second repair line arranged between a first pixel row and a second pixel row in the first area. Each of the first and second dummy pixels includes a first capacitor electrically connected to a dummy pixel circuit. The first capacitor of the first dummy pixel and the first capacitor of the second dummy pixel have different sizes.

This application claims priority to Korean Patent Application Number 10-2024-0157066 filed on Nov. 7, 2024, and all the benefits accruing therefrom under 35 U.S.C. § 119, the content of which in its entirety is herein incorporated by reference.

### BACKGROUND

### 1. Field

Embodiments of the invention relate to a display device, a method of repairing the same, and an electronic device including the display device.

### 2. Related Art

With the recent increase in interest in information display, research and development of display devices is ongoing.

### SUMMARY

The disclosure provides a display device, a repairing method thereof, and an electronic device including the display device which can improve reliability by preventing a dark spot failure of a pixel.

Aspects of some embodiments of the present disclosure include a display device including a substrate in which a display area including a first area and a second area and a non-display area surrounding at least one side of the display area are defined, a sub-pixel arranged in the display area, first and second dummy pixels arranged in the non-display area, and a repair line commonly provided to the display area and the non-display area and extending in a first direction. The non-display area includes a first non-display area adjacent to the first area and a second non-display area adjacent to the second area. The repair line includes a first repair line and a second repair line arranged between a first pixel row and a second pixel row of the substrate in the first area. Each of the first and second dummy pixels includes a dummy pixel circuit and a first capacitor electrically connected to the dummy pixel circuit. The first capacitor of the first dummy pixel and the first capacitor of the second dummy pixel have different sizes.

According to some embodiments, the second dummy pixel may be located closer to the first area than the first dummy pixel in the first non-display area, and the first capacitor of the first dummy pixel may have a greater size than the first capacitor of the second dummy pixel.

According to some embodiments, the first capacitor of each of the first and second dummy pixels may include a lower electrode arranged on the substrate, and an upper electrode arranged on the lower electrode with an insulating layer interposed therebetween. An overlap area between the lower electrode and the upper electrode in the first dummy pixel may be greater than an overlap area between the lower electrode and the upper electrode in the second dummy pixel.

According to some embodiments, the dummy pixel circuit of the first dummy pixel may be arranged between the first capacitor of the first dummy pixel and the first capacitor of the second dummy pixel in a plan view.

According to some embodiments, the first capacitor of the first dummy pixel and the first capacitor of the second dummy pixel may be arranged adjacent to each other in a plan view.

According to some embodiments, the upper electrode of the first capacitor of the first dummy pixel and the upper electrode of the first capacitor of the second dummy pixel may be common electrodes provided in common to the first dummy pixel and the second dummy pixel.

According to some embodiments, the first repair line and the second repair line may extend in the first direction. The first repair line and the second repair line may be spaced apart from each other in a second direction, and may be electrically isolated from each other.

According to some embodiments, the dummy pixel circuit of the first dummy pixel may be electrically connected to one of the first and second repair lines. The dummy pixel circuit of the second dummy pixel may be electrically connected to the other one of the first and second repair lines.

According to some embodiments, the dummy pixel circuit of the first dummy pixel may be electrically connected to the second repair line. The dummy pixel circuit of the second dummy pixel may be electrically connected to the first repair line.

According to some embodiments, the display device may further include a first bridge pattern located between the first repair line and the second repair line, extending in the second direction, and electrically connected to the first repair line, and a second bridge pattern located between the first repair line and the second repair line, extending in the second direction, and electrically connected to the second repair line.

According to some embodiments, the sub-pixel may include a pixel circuit including at least one transistor arranged on the substrate, a light-emitting element electrically connected to the transistor and emitting light, and a first contact electrode electrically connecting the light-emitting element and the transistor. The first contact electrode may overlap the first and second bridge patterns. The first contact electrode, the first bridge pattern, and the second bridge pattern may be electrically isolated from each other.

According to some embodiments, pixel circuits of two sub-pixels facing each other in the second direction while interposing the first and second repair lines in the first area may be mirror symmetrical relative to each other.

According to some embodiments, each of the first and second dummy pixels may further include a second contact electrode electrically connecting the dummy pixel circuit to a corresponding repair line among the first and second repair lines. The second contact electrode may overlap the first and second bridge patterns. The second contact electrode may be electrically connected to one of the first and second bridge patterns.

According to some embodiments, the repair line may further include a third repair line and a fourth repair line arranged between the first pixel row and the second pixel row in the second area. The dummy pixels further may include a third dummy pixel and a fourth dummy pixel arranged in the second non-display area to correspond to the first pixel row and the second pixel row, respectively. The third dummy pixel may be electrically connected to one of the third and fourth repair lines. The fourth dummy pixel may be electrically connected to the other one of the third and fourth repair lines.

According to some embodiments, each of the third and fourth dummy pixels may include the dummy pixel circuit and the first capacitor electrically connected to the dummy pixel circuit. The first capacitor of the third dummy pixel and the first capacitor of the fourth dummy pixel may have different sizes.

According to some embodiments, the third dummy pixel may be located closer to the second area than the fourth dummy pixel in the second non-display area. The first capacitor of the fourth dummy pixel may have a greater size than the first capacitor of the third dummy pixel.

Aspects of some embodiments of the present disclosure include a display device including a substrate in which a display area including a first area and a second area and a non-display area surrounding at least one side of the display area are defined, a sub-pixel arranged in the display area, a dummy pixel arranged in the non-display area, and a repair line provided in common to the display area and the non-display area and extending in a first direction. The repair line includes two repair lines arranged between a first pixel row and a second pixel row of the substrate and electrically isolated from each other. The non-display area includes a first non-display area adjacent to the first area and a second non-display area adjacent to the second area. The dummy pixel includes first and second dummy pixels arranged corresponding to the first pixel row and the second pixel row, respectively, in the first non-display area, and third and fourth dummy pixels arranged corresponding to the first pixel row and the second pixel row, respectively, in the second non-display area. Each of the first to fourth dummy pixels includes a dummy pixel circuit including at least one transistor and a first capacitor electrically connected to the dummy pixel circuit. The first capacitor of the first dummy pixel and the first capacitor of the second dummy pixel have different sizes. The first capacitor of the third dummy pixel and the first capacitor of the fourth dummy pixel have different sizes.

According to some embodiments, the second dummy pixel may be located closer to the first area than the first dummy pixel in the first non-display area. The third dummy pixel may be located closer to the second area than the fourth dummy pixel in the second non-display area. The first capacitor of the first dummy pixel may have a greater size than the first capacitor of the second dummy pixel. The first capacitor of the fourth dummy pixel may have a greater size than the first capacitor of the third dummy pixel.

Aspects of some embodiments of the present disclosure include a method of repairing a display device including a substrate in which a display area including a first area and a second area and a non-display area surrounding at least one side of the first and second areas are defined, a sub-pixel arranged in the display area and including a pixel circuit, a light-emitting element, and a contact electrode electrically connected to an anode electrode of the light-emitting element, first and second repair lines arranged between a first pixel row and a second pixel row and spaced apart from each other in the display area, a first dummy pixel and a second dummy pixel arranged in the non-display area corresponding to the first pixel row and the second pixel row, respectively, and connected to the first repair line and the second repair line, first bridge patterns electrically connected to the first repair line, and second bridge patterns electrically connected to the second repair line, the method including: separating a first defective pixel circuit arranged in a first pixel column of the first pixel row from a first light-emitting element corresponding to the first defective pixel circuit, electrically connecting an anode electrode of the first light-emitting element to a dummy pixel circuit of the first dummy pixel by electrically connecting the contact electrode electrically connected to the anode electrode of the first light-emitting element to a corresponding first bridge pattern among the first bridge patterns, separating a second defective pixel circuit arranged in a third pixel column of the first pixel row from a second light-emitting element corresponding to the second defective pixel circuit, and electrically connecting an anode electrode of the second light-emitting element to a dummy pixel circuit of the second dummy pixel by electrically connecting the contact electrode electrically connected to the anode electrode of the second light-emitting element to a second bridge pattern among the second bridge patterns. Each of the first and second dummy pixels includes a first capacitor electrically connected to the dummy pixel circuit. The first capacitor of the first dummy pixel and the first capacitor of the second dummy pixel have different sizes.

According to some embodiments, the second dummy pixel may be located closer to the display area than the first dummy pixel in the non-display area. The first capacitor of the first dummy pixel may have a greater size than the first capacitor of the second dummy pixel.

Aspects of some embodiments of the present disclosure include an electronic device including a processor providing input image data to a display device, and the display device displaying an image based on the input image data, wherein the display device may include a substrate in which a display area including a first area and a second area and a non-display area surrounding at least one side of the display area are defined, a sub-pixel arranged in the display area, a dummy pixel arranged in the non-display area, and a repair line commonly provided to the display area and the non-display area and extending in a first direction. The non-display area includes a first non-display area adjacent to the first area and a second non-display area adjacent to the second area. The repair line includes a first repair line and a second repair line arranged between a first pixel row and a second pixel row of the substrate in the first area. The dummy pixel includes a first dummy pixel and a second dummy pixel arranged in the first non-display area so as to correspond to the first pixel row and the second pixel row, respectively. Each of the first and second dummy pixels includes a dummy pixel circuit and a first capacitor electrically connected to the dummy pixel circuit. The first capacitor of the first dummy pixel and the first capacitor of the second dummy pixel have different sizes.

According to some embodiments, the second dummy pixel may be located closer to the first area than the first dummy pixel in the first non-display area. The first capacitor of the first dummy pixel may have a greater size than the first capacitor of the second dummy pixel.

### BRIEF DESCRIPTION OF THE DRAWINGS

The above and other features of embodiments of the invention will become more apparent by describing in further detail embodiments thereof with reference to the accompanying drawings, in which:

FIG. 1 is a schematic block diagram illustrating a display device according to one embodiment.

FIG. 2 is a schematic plan view illustrating a display device according to one embodiment.

FIG. 3 is a schematic diagram illustrating an embodiment of one sub-pixel among sub-pixels of FIG. 2.

FIG. 4 is a schematic diagram illustrating an embodiment of one dummy pixel among dummy pixels of FIG. 2.

FIG. 5 is a schematic plan view illustrating an embodiment of one pixel among pixels of FIG. 2.

FIG. 6 is a schematic cross-sectional view along line I-I′ in FIG. 5.

FIG. 7 is a schematic plan view illustrating sub-pixels arranged in a first row and a second row located in a portion of a first area of a display area of a display device according to one embodiment.

FIG. 8 is a schematic plan view illustrating only the configurations included in first to seventh transistors of FIG. 7 and a first conductive layer.

FIG. 9 is a schematic plan view illustrating only the configurations included in a second conductive layer of FIG. 7.

FIG. 10 is a schematic plan view illustrating only the configurations included in a third conductive layer of FIG. 7.

FIG. 11 is a schematic plan view illustrating only the configurations included in a fourth conductive layer of FIG. 7.

FIG. 12 is a schematic plan view illustrating only the configurations included in a fifth conductive layer of FIG. 7.

FIG. 13 is a schematic plan view illustrating dummy pixels arranged in first and second rows located in a first area of a first non-display area of a display device according to one embodiment.

FIG. 14 is a schematic plan view illustrating only the configurations of first to sixth transistors, eighth and ninth transistors, and a first conductive layer of FIG. 13.

FIG. 15 is a schematic plan view illustrating only the configurations included in the second conductive layer of FIG. 13.

FIG. 16 is a schematic plan view illustrating only the configurations included in a third conductive layer of FIG. 13.

FIG. 17 is a schematic plan view illustrating only the configurations included in a fourth conductive layer of FIG. 13.

FIG. 18 is a schematic plan view of only the configurations included in a fifth conductive layer in FIG. 13.

FIG. 19 is a schematic plan view illustrating dummy pixels arranged in first and second rows located in a portion of a first non-display area of a display device according to one embodiment.

FIG. 20 is a schematic plan view illustrating only the configurations included in first to sixth transistors, eighth and ninth transistors, and a first conductive layer of FIG. 19.

FIG. 21 is a schematic plan view illustrating only the configurations included in the second conductive layer of FIG. 19.

FIG. 22 is a view of a portion EA1 of FIG. 2 for illustrating sub-pixels in a first area and dummy pixels in a first non-display area in a display device according to one embodiment.

FIG. 23 is a schematic flow diagram illustrating a method of repairing a display device according to one embodiment.

FIG. 24 is a schematic view for illustrating a method of repairing a bad sub-pixel corresponding to the portion EA1 of FIG. 2.

FIG. 25 is a schematic circuit diagram illustrating electrical connections of a first sub-pixel and a second dummy pixel arranged in a first row of FIG. 24.

FIG. 26 is a schematic view for illustrating a method of repairing a bad sub-pixel corresponding to the portion EA1 of FIG. 2.

FIG. 27 is a schematic view of a portion EA2 of FIG. 2 for illustrating sub-pixels in a second area and dummy pixels in a second non-display area in a display device according to one embodiment.

FIG. 28 is a schematic view for illustrating a method of repairing a bad sub-pixel corresponding to the portion EA2 of FIG. 2.

FIG. 29 is a schematic block diagram illustrating an electronic device according to embodiments.

FIG. 30 is a perspective view illustrating an example in which an electronic device of FIG. 29 is a smartphone.

FIG. 31 is a perspective view illustrating an example in which an electronic device of FIG. 29 is a tablet PC.

FIG. 32 is schematic flow diagram illustrating a method of repairing a display device according to one embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In describing the drawings, like reference numerals have been used for like elements. In the accompanying drawings, the dimensions of the structures are enlarged than the actual size in order to clearly explain the invention. It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following description, when a first part is “connected” to a second part, this includes not only the case where the first part is directly connected to the second part, but also the case where a third part is interposed therebetween and they are connected to each other.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments of the invention will be described in detail with reference to the accompanying drawings.

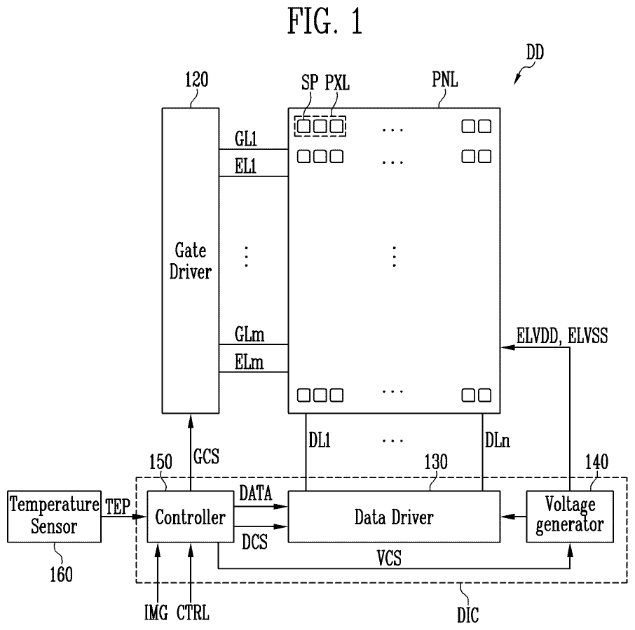

FIG. 1 is a schematic block diagram illustrating a display device DD according to one embodiment.

Referring to FIG. 1, the display device DD may include a display panel PNL, a gate driver 120, a data driver 130, a voltage generator 140, and a controller 150.

The display panel PNL may include sub-pixels SP. The sub-pixels SP may be connected to the gate driver 120 through first to m-th gate lines GL1 to GLm. The sub-pixels SP may be connected to the data driver 130 through first to nth data lines DL1 to DLn.

Each of the sub-pixels SP may include at least one light-emitting element configured to generate light. Accordingly, each of the sub-pixels SP may generate light of a particular color, such as red, green, blue, cyan, magenta, yellow, or the like. Two or more of the sub-pixels SP may constitute a single pixel PXL. For example, as shown in FIG. 1, three sub-pixels SP may constitute a single pixel PXL.

The gate driver 120 may be coupled to the sub-pixels SP arranged in a row direction through the first to m-th gate lines GL1 to GLm. The gate driver 120 may output gate signals to the first to m-th gate lines GL1 to GLm in response to a gate control signal GCS. The gate driver 120 may be arranged on one side of the display panel PNL, but is not limited thereto.

In embodiments, first to m-th emission control lines EL1 to ELm which are connected to the sub-pixels SP in the row direction may be further provided. The gate driver 120 may include an emission control driver configured to control the first to m-th emission control lines EL1 to ELm. The emission control driver may be operable under the control of the controller 150.

The data driver 130 may be connected to the sub-pixels SP arranged in a column direction through the first to nth data lines DL1 to DLn. The data driver 130 may receive image data DATA and data control signals DCS from the controller 150. The data driver 130 may operate in response to the data control signals DCS.

The data driver 130 may apply data signals having grayscale voltages corresponding to the image data DATA to the first to nth data lines DL1 to DLn by using the voltages from the voltage generator 140. When a gate signal is applied to each of the first to m-th gate lines GL1 to GLm, the data signals corresponding to the image data DATA may be applied to the data lines DL1 to DLn. Accordingly, the corresponding sub-pixels SP may generate light corresponding to the data signals. Accordingly, an image may be displayed on the display panel PNL.

In embodiments, the gate driver 120 and the data driver 130 may include complementary metal-oxide semiconductor (CMOS) circuit elements.

The voltage generator 140 may be operable in response to a voltage control signal VCS from the controller 150. The voltage generator 140 may generate a plurality of voltages and provide the generated voltages to components of the display device DD. For example, the voltage generator 140 may receive an input voltage from outside the display device DD, control the input voltage, and regulate the controlled voltage to thereby generate the plurality of voltages.

The voltage generator 140 may generate a first power supply voltage ELVDD and a second power supply voltage ELVSS, and the generated first and second power supply voltages ELVDD and ELVSS may be provided to the sub-pixels SP. The first power supply voltage ELVDD may have a relatively high voltage level, and the second power supply voltage ELVSS may have a lower voltage level than the first power supply voltage ELVDD. In other embodiments, the first power supply voltage ELVDD or the second power supply voltage ELVSS may be provided by an external device to the display device DD.

In addition, the voltage generator 140 may generate various voltages. For example, the voltage generator 140 may generate an initialization voltage which is applied to the sub-pixels SP. For example, a predetermined reference voltage may be applied to the first to nth data lines DL1 to DLn during a sensing operation to sense the electrical characteristics of the transistors and/or light-emitting elements of the sub-pixels SP, and the voltage generator 140 may generate the reference voltage.

The controller 150 may control various operations of the display device DD. The controller 150 may receive a control signal CTRL from an external source to control the input image data IMG and the display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel PNL to output the image data DATA. In embodiments, the controller 150 may output the image data DATA by aligning the input image data IMG to fit the sub-pixels SP in a row unit.

Two or more components among the data driver 130, the voltage generator 140, and the controller 150 may be mounted on a single integrated circuit. As shown in FIG. 1, the data driver 130, the voltage generator 140, and the controller 150 may be included in a driver integrated circuit DIC. The data driver 130, the voltage generator 140, and the controller 150 may be functionally distinct components within the single driver integrated circuit DIC. In other embodiments, at least one of the data driver 130, the voltage generator 140, and the controller 150 may be provided as a separate component in the driver integrated circuit DIC.

The display device DD may include at least one temperature sensor 160. The temperature sensor 160 may be configured to sense temperature in the vicinity thereof and generate temperature data TEP indicative of the sensed temperature. In embodiments, the temperature sensor 160 may be arranged adjacent to the display panel PNL and/or the driver integrated circuit DIC.

The controller 150 may control various operations of the display device DD in response to the temperature data TEP. In embodiments, the controller 150 may adjust the brightness of the image output from the display panel PNL in response to the temperature data TEP.

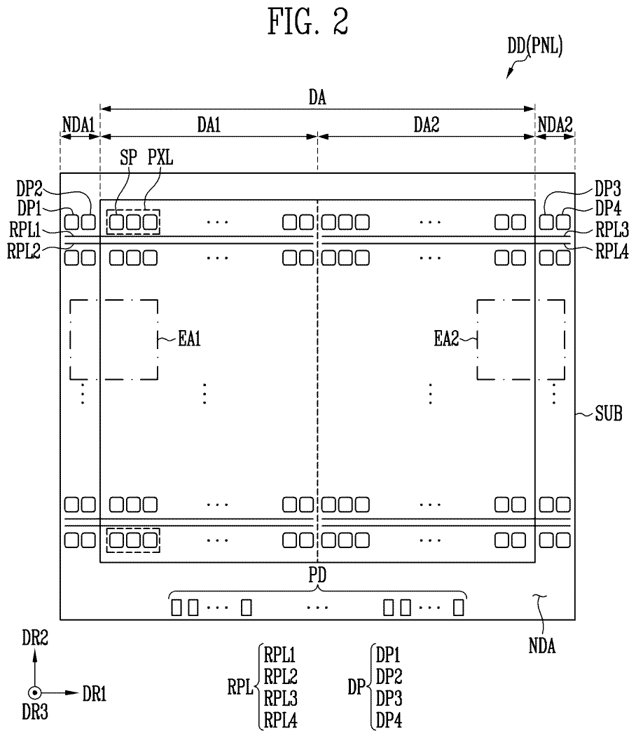

FIG. 2 is a schematic plan view illustrating the display device DD according to one embodiment. For convenience, FIG. 2 schematically illustrates the structure of a display area DA of the display device DD where an image is displayed, for example, the structure of the display panel PNL provided in the display device DD. As used herein, the “plan view” is a view in a thickness direction (i.e., a third direction DR3) of the display device DD (or substrate SUB).

Referring to FIG. 2, the display device DD (or the display panel PNL) may include a substrate SUB and the sub-pixels SP.

The display device DD may have various shapes, for example, but not limited to, a rectangular plate having two pairs of sides parallel to each other. The present embodiments may be applicable when the display device DD is an electronic device with a display surface on at least one side thereof, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, a or wearable device.

The substrate SUB may include a transparent insulating material which allows light to pass therethrough. The substrate SUB may be a rigid substrate or a flexible substrate.

The rigid substrate may be one of, for example, a glass substrate, a quartz substrate, a glass-ceramic substrate, and a crystalline glass substrate.

The flexible substrate may be one of a film substrate and a plastic substrate which includes a polymer organic material. For example, the flexible substrate may include at least one of polystyrene, polyvinyl alcohol, polymethylmethacrylate, polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate as well as one or more combinations thereof.

The sub-pixels SP may be arranged in the display area DA on the substrate SUB. The sub-pixels SP may be arranged in a matrix form along a first direction DR1 and a second direction DR2 crossing the first direction DR1, but the arrangement of the sub-pixels SP is not limited thereto. For example, the sub-pixels SP may be arranged in a zigzag pattern in the first direction DR1 and the second direction DR2. For example, the sub-pixels SP may be arranged in a PENTILE™ arrangement structure. The first direction DR1 may be a row direction and the second direction DR2 may be a column direction.

Two or more sub-pixels SP among the plurality of sub-pixels SP may include the single pixel PXL.

One area of the substrate SUB may be provided as the display area DA on which the sub-pixels SP are placed, and the remaining area of the substrate SUB may be provided as a non-display area NDA.

In the non-display area NDA on the substrate SUB, components for controlling the sub-pixels SP may be arranged. For example, wiring associated with the sub-pixels SP, such as the first to m-th gate lines GL1 to GLm and the first to nth data lines DL1 to DLn as shown FIG. 1 may be arranged in the non-display area NDA.

In an embodiment, the display area DA may include a first area DA1 (or a first display area) and a second area DA2 ((or the second display area)) adjacent in the first direction DR1. By bisecting the display area DA around an imaginary line located at the center, the display area DA may be divided into the first area DA1 and the second area DA2. When viewed in plan, the first area DA1 may be located on the left side and the second area DA2 may be located on the right side.

The non-display area NDA may include a first non-display area NDA1 surrounding, abutting or extending edge-wise along an edge of at least one side of the first area DA1 and a second non-display area NDA2 surrounding, abutting or extending edge-wise along an edge of at least one side of the second area DA2.

In each of the first and second non-display areas NDA1 and NDA2, two dummy pixels DP corresponding to each pixel row may be arranged. For example, the non-display area NDA may have two dummy pixels DP corresponding to each pixel row. The dummy pixels DP may include first and second dummy pixels DP1 and DP2 arranged in the first non-display area NDA1 and third and fourth dummy pixels DP3 and DP4 arranged in the second non-display area NDA2.

The first dummy pixel DP1 and a second dummy pixel DP2 may be arranged adjacent to one another in the first direction DR1 in the first non-display area NDA1. The third dummy pixel DP3 and the fourth dummy pixel DP4 may be arranged adjacent to one another in the first direction DR1 in the second non-display area NDA2. The second dummy pixel DP2 may be arranged closer to the first area DA1 (or the display area DA) than the first dummy pixel DP1, and the third dummy pixel DP3 may be arranged closer to the second area DA2 (or the display area DA) than the fourth dummy pixel DP4.

Pads PD may be arranged in the non-display area NDA on the substrate SUB. The pads PD may be electrically connected to the sub-pixels SP through wiring. For example, the pads PD may be connected to the sub-pixels SP through the first to nth data lines DL1 to DLn as described above with reference to FIG. 1.

The pads PD may interface other components of the display device DD through the display panel PNL. In embodiments, the voltages and signals required to operate the components included in the display panel PNL may be provided through the pads PD from the driver integrated circuit DIC of FIG. 1.

In embodiments, the display device DD may include repair lines RPL provided in common across the display area DA and the non-display area NDA. The repair lines RPL may include a first repair line RPL1, a second repair line RPL2, a third repair line RPL3, and a fourth repair line RPL4. The first repair line RPL1 and the second repair line RPL2 may be provided in common to extend in parallel across the first area DA1 and the first non-display area NDA1. The third repair line RPL3 and the fourth repair line RPL4 may be provided in common to extend in parallel across the second area DA2 and the second non-display area NDA2.

In the first area DA1, the first repair line RPL1 and the second repair line RPL2 may be arranged between two sub-pixels SP facing each other in the second direction DR2. In the first non-display area NDA1, the first repair line RPL1 and the second repair line RPL2 may be arranged between two first dummy pixels DP1 facing each other in the second direction DR2 and between two second dummy pixels DP2 facing each other in the second direction DR2, respectively.

In the second area DA2, the third repair line RPL3 and the fourth repair line RPL4 may be arranged between two sub-pixels SP facing each other in the second direction DR2. In the second non-display area NDA2, the third repair line RPL3 and the fourth repair line RPL4 may be arranged between two third dummy pixels DP3 facing each other in the second direction DR2 and between two fourth dummy pixels DP4 facing each other in the second direction DR2, respectively.

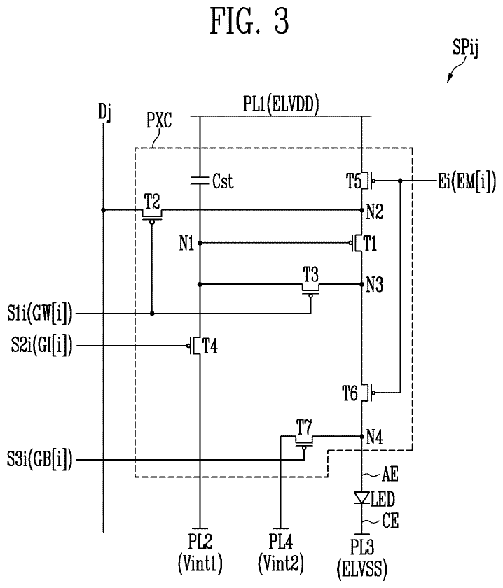

FIG. 3 is a schematic diagram illustrating an embodiment of a sub-pixel SPij which is one of the sub-pixels of FIG. 2. For convenience of description, FIG. 3 illustrates the sub-pixel SPij located on an i-th horizontal line (or an i-th pixel row) and connected to a j-th data line Dj.

Referring to FIGS. 2 and 3, the sub-pixel SPij may be arranged on the i-th horizontal line.

The sub-pixel SPij may include a light-emitting element LED and a pixel circuit PXC. The pixel circuit PXC may include first, second, third, fourth, fifth, sixth, and seventh transistors T1, T2, T3, T4, T5, T6, and T7, and a storage capacitor Cst.

The first transistor T1 may be electrically connected between the first power line PL1 and an anode electrode AE of the light-emitting element LED. The first transistor T1 may include a gate electrode electrically connected to a first node N1. The first transistor T1 may control the amount of current (or a driving current flowing from the first power line PL1 to the third power line PL3 through the light-emitting element LED based on a voltage at the first node N1). The first power line PL1 is supplied with the first power supply voltage ELVDD, the third power line PL3 is supplied with the second power supply voltage ELVSS, and the first power supply voltage ELVDD may be set to a voltage higher than the second power supply voltage ELVSS.

The second transistor T2 may be electrically connected between a j-th data line Dj and a second node N2. A gate electrode of the second transistor T2 may be connected to a 1i-th scan line S1i (or the first scan line). The second transistor T2 may be turned on when a first scan signal GW[i] (e.g., a low-level first scan signal) is supplied to the 1i-th scan line S1i to electrically connect the j-th data line Dj and the second node N2. When each of the first transistor T1 and the third transistor T3 is in a turn-on state, the second transistor T2 may transfer a data signal of the j-th data line Dj to the second node N2 in response to the first scan signal GW[i].

The third transistor T3 may be electrically connected between the first node N1 and a third node N3. A gate electrode of the third transistor T3 may be electrically connected to the 1i-th scan line S1i. The third transistor T3 may be turned on when the first scan signal GW[i] is supplied to the 1i-th scan line S1i. When the third transistor T3 is turned on, the first transistor T1 may be diode-connected.

The fourth transistor T4 may be electrically connected between the first node N1 and a second power line PL2. A gate electrode of the fourth transistor T4 may be electrically connected to a 2i-th scan line S2i (the second scan line). The second power line PL2 may be provided with a first initialization power supply voltage Vint1. The fourth transistor T4 may be turned on by a second scan signal GI[i] supplied to the 2i-th scan line S2i. When the fourth transistor T4 is turned on, the first initialization power supply voltage Vint1 may be supplied to the first node N1 (i.e., a gate electrode of the first transistor T1).

A fifth transistor T5 may be electrically connected between the first power line PL1 and the second node N2. The gate electrode of the fifth transistor T5 may be electrically connected to an i-th emission control line Ei. The sixth transistor T6 may be electrically connected between the third node N3 and the light-emitting element LED (or a fourth node N4). A gate electrode of the sixth transistor T6 may be electrically connected to the i-th emission control line Ei. The fifth transistor T5 and the sixth transistor T6 may be turned off when an emission control signal EM[i] (e.g., a high-level emission control signal EM[i]) is supplied to the i-th emission control line Ei, and may be turned on otherwise.

The seventh transistor T7 may be electrically connected between the anode electrode AE (i.e., the fourth node N4) of the light-emitting element LED and a fourth power line PL4. A gate electrode of the seventh transistor T7 may be electrically connected to a 3i-th scan line S3i. The fourth power line PL4 may be supplied with a second initialization power supply voltage Vint2. The seventh transistor T7 may be turned on by a third scan signal GB[i] supplied to the 3i-th scan line S3i to supply the second initialization power supply voltage Vint2 to the anode electrode AE of the light-emitting element LED. The second initialization power supply voltage Vint2 may be the same as the first initialization power supply voltage Vint1, but is not limited thereto.

The light-emitting element LED may include the anode electrode AE and a cathode electrode CE. The anode electrode AE may be connected to the fourth node N4 and the cathode electrode CE may be connected to the third power line PL3. The cathode electrode CE of the light-emitting element LED may be supplied with the second power supply voltage ELVSS. The light-emitting element LED may receive a driving current from the first transistor T1 and emit light.

In an embodiment, the pixel circuit PXC may include a P-type transistor. For example, the first to seventh transistors T1 to T7 may include polysilicon transistors including silicon semiconductors and may include a polysilicon semiconductor layer as an active layer. For example, the active layer may be formed through a low-temperature polysilicon process (e.g., a low-temperature poly-silicon (LTPS) process).

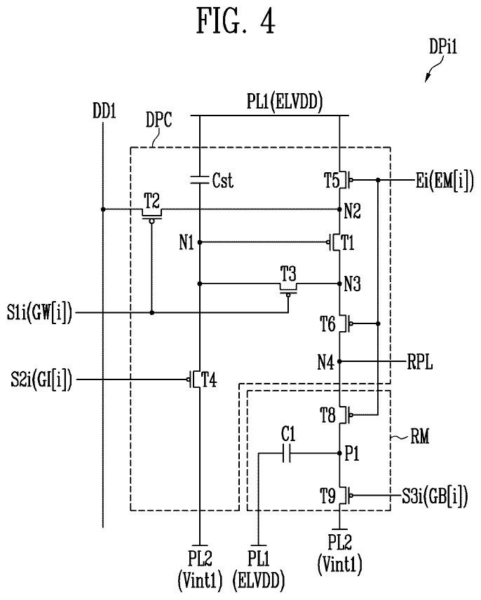

FIG. 4 is a schematic diagram illustrating an embodiment of a dummy pixel DPi1 which is one of the dummy pixels of FIG. 2. For convenience of description, FIG. 4 illustrates the dummy pixel DPi1 located on the i-th horizontal line (or the i-th pixel row) in the first non-display area and coupled to a first dummy data line DD1.

Referring to FIG. 4, for convenience of description, an overlapping description with the above-described embodiments will be omitted.

Referring to FIGS. 2 and 4, the dummy pixel DPi1 may be arranged on the i-th horizontal line.

The dummy pixel DPi1 may include a dummy pixel circuit DPC and a repair modulation circuit RM.

The dummy pixel circuit DPC may include first, second, third, fourth, fifth, and sixth transistors T1, T2, T3, T4, T5, and T6, and the storage capacitor Cst. In other words, the dummy pixel circuit DPC may include substantially the same configuration as the pixel circuit PXC described with reference to FIG. 3, except for the seventh transistor T7.

The repair modulation circuit RM may include an eighth transistor T8, a ninth transistor T9, and a first capacitor C1. The repair modulation circuit RM is connected to a repair line RPL, the i-th emission control line Ei, and the 3i-th scan line S3i.

The eighth transistor T8 may be electrically connected between the fourth node N4 and a connection node P1. A gate electrode of the eighth transistor T8 may be connected to the i-th emission control line Ei. A first input/output terminal of the eighth transistor T8 may be electrically connected to the fourth node N4 (or a node electrically connecting the repair line RPL and a light-emitting element of a defective sub-pixel), and a second input/output terminal of the eighth transistor T8 may be electrically connected to the first capacitor C1 and the connection node P1 of the ninth transistor T9.

The ninth transistor T9 may be electrically connected between the eighth transistor T8 and the second power line PL2. A gate electrode of the ninth transistor T9 may be electrically connected to the 3i-th scan line S3i. A first input/output terminal of the ninth transistor T9 may be electrically connected to the connection node P1, and a second input/output terminal of the ninth transistor T9 may be electrically connected to the second power line PL2.

One terminal of the first capacitor C1 is connected to the connection node P1 (or between the second input/output terminal of the eighth transistor T8 and the first input/output terminal of the ninth transistor T9), and the other terminal of the first capacitor C1 may be electrically connected to the first power line PL1.

In the dummy pixel DPi1, the fourth node N4 may be electrically connected to the repair line RPL. When the sub-pixel SP of the display area DA fails, the wiring between the anode electrode of the light-emitting element of the defective sub-pixel and the sixth transistor T6 may be disconnected, and the anode electrode and the repair line RPL may be connected so that the light-emitting element of the defective sub-pixel may emit light normally. A detailed description of the repairing method of the defective sub-pixel will be described below.

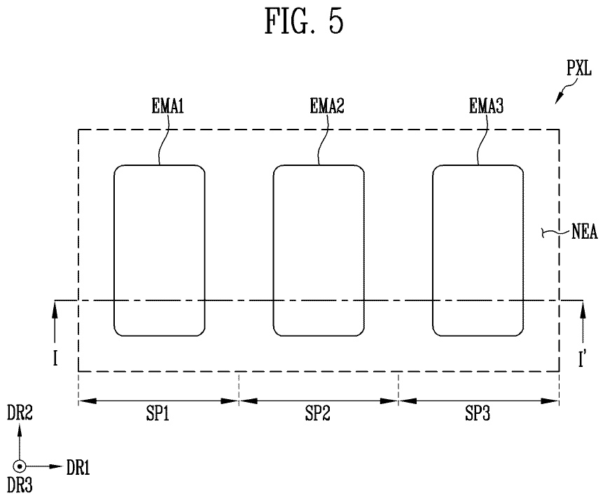

FIG. 5 is a schematic plan view illustrating an embodiment of one pixel among pixels of FIG. 2.

Referring to FIGS. 2 and 5, the pixel PXL may include a first sub-pixel SP1, a second sub-pixel SP2, and a third sub-pixel SP3 arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The first emission area EMA1 may be an area where light is emitted from the light-emitting element (see “LED” in FIG. 3) corresponding to the first sub-pixel SP1. The second emission area EMA2 may be an area where light is emitted from the light-emitting element LED corresponding to the second sub-pixel SP2. The third emission area EMA3 may be an area where light is emitted from the light-emitting element LED corresponding to the third sub-pixel SP3.

The first sub-pixel SP1, the second sub-pixel SP2, and the third sub-pixel SP3 may have substantially the same area, but are not limited thereto. In some embodiments, the second sub-pixel SP2 may have a greater area than the first sub-pixel SP1, and the third sub-pixel SP3 may have a greater area than the second sub-pixel SP2.

The first sub-pixel SP1, the second sub-pixel SP2, and the third sub-pixel SP3 may have a polygonal shape. For example, the first sub-pixel SP1, the second sub-pixel SP2, and the third sub-pixel SP3 may have a square shape or a hexagonal shape, but are not limited thereto.

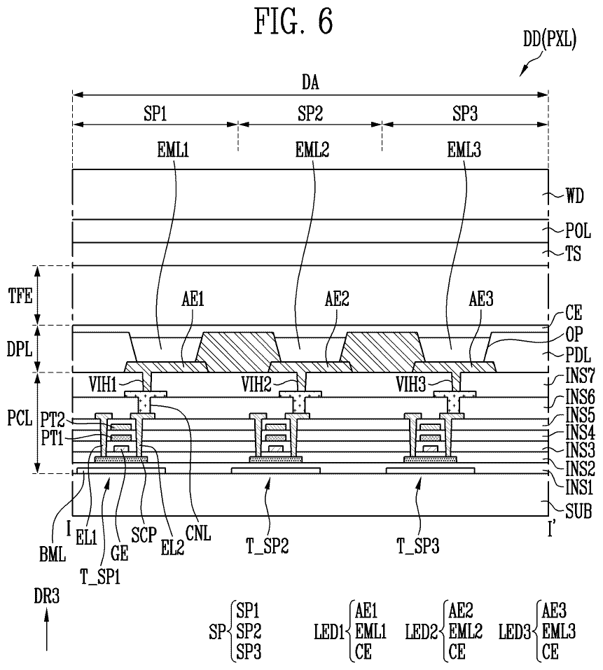

FIG. 6 is a schematic cross-sectional view along line I-I′ in FIG. 5.

In FIG. 6, for convenience of description, a cross-sectional structure or stacked structure of the display device DD, mainly based on the pixels PXL included in the display device DD, is briefly illustrated, and a thickness direction of the substrate SUB is shown as the third direction DR3.

Referring to FIGS. 5 and 6, the display device DD may include one or more pixels PXL arranged in the display area DA.

The pixel PXL may include one or more sub-pixels SP. For example, the pixel PXL may include the first sub-pixel SP1, the second sub-pixel SP2, and the third sub-pixel SP3. In an embodiment, the first sub-pixel SP1 may be a red sub-pixel, the second sub-pixel SP2 may be a green sub-pixel, and the third sub-pixel SP3 may be a blue sub-pixel, but the present disclosure is not limited thereto. Hereinafter, the first sub-pixel SP1, the second sub-pixel SP2, and the third sub-pixel SP3 are collectively referred to as the sub-pixel SP and/or the sub-pixels SP.

Each of the first to third sub-pixels SP1 to SP3 may include the substrate SUB, a pixel circuit layer PCL, a display element layer DPL, a thin film encapsulation layer TFE, and a window WD.

The substrate SUB may include a transparent insulating material which allows light to pass therethrough. The substrate SUB may be a rigid substrate or a flexible substrate.

The pixel circuit layer PCL of the sub-pixels SP may be arranged on the substrate SUB. One or more insulating layers may be arranged on the pixel circuit layer PCL. The insulating layers may include a first insulating layer INS1, a second insulating layer INS2, a third insulating layer INS3, a fourth insulating layer INS4, a fifth insulating layer INS5, a sixth insulating layer INS6, and a seventh insulating layer INS7 stacked sequentially on the substrate SUB in the third direction DR3. The insulating layers arranged on the pixel circuit layer PCL are not limited to the above-described embodiments, and other insulating layers may be added or some insulating layers may be omitted.

The first insulating layer INS1 may be arranged on the substrate SUB. The first insulating layer INS1 may prevent impurities from diffusing into circuit elements (or driving elements) constituting the pixel circuit (see “PXC” in FIG. 3), for example, transistors. The first insulating layer INS1 may be an inorganic layer including an inorganic material (or substance). The first insulating layer INS1 may include at least one of silicon nitride (SiNₓ), silicon oxide (SiOₓ), silicon oxynitride (SiOₓN_{y}), and aluminum oxide (AlOₓ) as well as one or more combinations thereof. The first insulating layer INS1 may be provided as a single layer, but may also be provided as multiple layers of at least two or more layers. The first insulating layer INS1 may be omitted depending on the material and process conditions of the substrate SUB.

The second insulating layer INS2 may be arranged on the first insulating layer INS1. The second insulating layer INS2 may include the same material as the first insulating layer INS1 or may include a material suitable (or selected) from among the materials exemplified as the constituents of the first insulating layer INS1. For example, the second insulating layer INS2 may be an inorganic layer including an inorganic material.

The third insulating layer INS3 may be arranged on the second insulating layer INS2. The third insulating layer INS3 may include the same material as the first insulating layer INS1 or may include one or more materials suitable (or selected) from among the materials exemplified as the constituents of the first insulating layer INS1.

The fourth insulating layer INS4 may be arranged on the third insulating layer INS3. The fourth insulating layer INS4 may be an inorganic layer including an inorganic material or an organic layer including an organic material.

The fifth insulating layer INS5 may be arranged on the fourth insulating layer INS4. The fifth insulating layer INS5 may include the same material as the first insulating layer INS1 or may include one or more materials suitable (or selected) from among the materials exemplified as the constituents of the first insulating layer INS1.

The sixth insulating layer INS6 (or a first via layer) may be arranged on the fifth insulating layer INS5. The sixth insulating layer INS6 may be an inorganic layer including an inorganic material or an organic layer including an organic material. The inorganic layer may include, for example, at least one of silicon oxide (SiOₓ), silicon nitride (SiNₓ), silicon oxynitride (SiOₓN_{y}), and aluminum oxide (AlOₓ) as well as one or more combinations thereof. The organic layer may be, for example, a polyacrylates resin, an epoxy resin, a phenolic resin, a polyamides resin, a polyimides resin, an unsaturated polyesters resin, an unsaturated polyester resin, a poly-phenylen ethers resin, a poly-phenylene sulfides resin, and a benzocyclobutene resin as well as one or more combinations thereof. In one embodiment, the sixth insulating layer INS6 may be an organic layer including an organic material.

The seventh insulating layer INS7 (or a second through layer) may be arranged on the sixth insulating layer INS6. The seventh insulating layer INS7 may include the same material as the sixth insulating layer INS6 or may include one or more materials suitable (or selected) from among the materials exemplified as the constituents of the sixth insulating layer INS6. For example, the seventh insulating layer INS7 may be an organic layer including an organic material.

The pixel circuit layer PCL may include one or more conductive layers arranged between the above-described insulating layers. For example, the conductive layers may include a first conductive layer arranged between the second insulating layer INS2 and the third insulating layer INS3, a second conductive layer arranged between the third insulating layer INS3 and the fourth insulating layer INS4, a third conductive layer arranged between the fourth insulating layer INS4 and the fifth insulating layer INS5, a fourth conductive layer arranged between the fifth insulating layer INS5 and the sixth insulating layer INS6, and a fifth conductive layer arranged between the sixth insulating layer INS6 and the seventh insulating layer INS7. However, the insulating layers and the conductive layers are not limited to the above-described embodiments, and other insulating layers and other conductive layers in addition to the above insulating layers and the above conductive layers may be arranged in the pixel circuit layer PCL according to embodiments.

The pixel circuit layer PCL may include circuit elements (or driving elements) of each of the first to third sub-pixels SP1 to SP3. For example, the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 is one of the transistors included in the pixel circuit PXC of the first sub-pixel SP1. The transistor T_SP2 of the second sub-pixel SP2 is one of the transistors included in the pixel circuit PXC of the second sub-pixel SP2. The transistor T_SP3 of the third sub-pixel SP3 is one of the transistors included in the pixel circuit PXC of the third sub-pixel SP3. In FIG. 6, one of the transistors of each sub-pixel SP is shown, and the other circuit elements are omitted for clarity and simplicity.

The transistor T_SP1 of the first sub-pixel SP1 may include a semiconductor pattern SCP, a gate electrode GE, a first terminal EL1, and a second terminal EL2.

The gate electrode GE may be arranged on the second insulating layer INS2 and covered by the third insulating layer INS3. For example, the gate electrode GE may be a first conductive layer (or a first gate conductive layer) located between the second insulating layer INS2 and the third insulating layer INS3. The gate electrode GE may overlap a portion of the semiconductor pattern SCP. For example, the gate electrode GE may overlap an active pattern of the semiconductor pattern SCP.

The pixel circuit layer PCL may include a first pattern PT1 arranged between the third insulating layer INS3 and the fourth insulating layer INS4. The first pattern PT1 may include a second conductive layer (or a second gate conductive layer). According to embodiments, the first pattern PT1 may overlap the gate electrode GE between the third insulating layer INS3 interposed therebetween in a plan view to form a capacitor. Further, the pixel circuit layer PCL may include a second pattern PT2 arranged between the fourth insulating layer INS4 and the fifth insulating layer INS5. The second pattern PT2 may include a third conductive layer (or a third gate conductive layer). According to embodiments, the second pattern PT2 may be utilized as signal lines, connection means, etc. which are electrically connected to the transistors.

The semiconductor pattern SCP may be arranged on the first insulating layer INS1 and covered by the second insulating layer INS2. The semiconductor pattern SCP may be a semiconductor layer including polysilicon, amorphous silicon, oxide semiconductor, or the like. The semiconductor pattern SCP may include an active pattern, a first contact region, and a second contact region. The active pattern, the first contact region, and the second contact region may include an undoped or impurity-doped semiconductor layer. For example, the first contact region and the second contact region may include a semiconductor layer doped with an impurity, and the active pattern may be a region doped at a lower concentration than the first and second contact regions. Accordingly, the conductivity of the first and second contact regions may be greater than the conductivity of the active pattern. The first and second contact regions may be source/drain regions (or source/drain electrodes) of the transistor T_SP1 of the first sub-pixel SP1.

The active pattern of the semiconductor pattern SCP may be a channel region which overlaps the gate electrode GE. A first contact region of the semiconductor pattern SCP may contact one end of the active pattern. The first contact region may be electrically connected to the first terminal EL1. A second contact area of the semiconductor pattern SCP may contact the other end of the active pattern. The second contact area may be electrically connected to the second terminal EL2.

The first terminal EL1 may be provided and/or formed on the fifth insulating layer INS5. For example, the first terminal EL1 may include a fourth conductive layer (or a first source-drain conductive layer) formed between the fifth insulating layer INS5 and the sixth insulating layer INS6. The first terminal EL1 may be in contact with the first contact region of the semiconductor pattern SCP through contact holes passing through the fifth insulating layer INS5, the fourth insulating layer INS4, the third insulating layer INS3, and the second insulating layer INS2.

The second terminal EL2 may be provided and/or formed on the fifth insulating layer INS5. The second terminal EL2 may include a fourth conductive layer formed between the fifth insulating layer INS5 and the sixth insulating layer INS6. The second terminal EL2 may be in contact with the second contact region of the semiconductor pattern SCP through contact holes passing through the fifth insulating layer INS5, the fourth insulating layer INS4, the third insulating layer INS3, and the second insulating layer INS2.

The second terminal EL2 may be electrically connected to a connection line CNL arranged on the sixth insulating layer INS6. The connection line CNL may be a fifth conductive layer (or a second source-drain conductive layer) arranged between the sixth insulating layer INS6 and the seventh insulating layer INS7.

According to an embodiment, a bottom metal pattern BML may be arranged on a lower side of the transistor T_SP1 of the first sub-pixel SP1 as described above. The bottom metal pattern BML may be a dummy conductive layer located between the substrate SUB and the first insulating layer INS1.

As the gate electrode GE, the first terminal EL1, and the second terminal EL2 are electrically connected to other circuit elements and/or wiring, the transistor T_SP1 of the first sub-pixel SP1 may be provided as one of the transistors constituting the pixel circuit PXC of the first sub-pixel SP1.

Each of the transistor T_SP2 of the second sub-pixel SP2 and the transistor T_SP3 of the third sub-pixel SP3 may be configured substantially the same as the transistor T_SP1 of the first sub-pixel SP1.

As described above, the pixel circuit layer PCL may include circuit elements for each of the first to third sub-pixels SP1 to SP3.

The display element layer DPL may be arranged on the pixel circuit layer PCL. The display element layer DPL may include a light-emitting element (see “LED” in FIG. 3) and a pixel defining layer PDL. The light-emitting element LED may include an anode electrode, a light emitting layer, and the cathode electrode CE. The light-emitting element LED may be provided in each of Each of the first to third sub-pixels SP1 to SP3 may be equipped with the. The light-emitting element LED provided in the first sub-pixel SP1 may be a first light-emitting element LED1, the light-emitting element LED provided in the second sub-pixel SP2 may be a second light-emitting element LED2, and the light-emitting element LED provided in the third sub-pixel SP3 may be a third light-emitting element LED3.

A first anode electrode AE1 may be arranged on the pixel circuit layer PCL (or the seventh insulating layer INS7) of the first sub-pixel SP1, a second anode electrode AE2 may be arranged on the pixel circuit layer PCL of the second sub-pixel SP2, and a third anode electrode AE3 may be arranged on the pixel circuit layer PCL of the third sub-pixel SP3. Each of the first to third anode electrodes AE1 to AE3 may be electrically connected to a circuit element arranged on the pixel circuit layer PCL through a via hole passing through the seventh insulating layer INS7. For example, the first anode electrode AE1 is electrically connected to the transistor T_SP1 of the first sub-pixel SP1 through a first via hole VIH1 penetrating the seventh insulating layer INS7, the second anode electrode AE2 may be electrically connected to the transistor T_SP2 of the second sub-pixel SP2 through a second via hole VIH2 penetrating the seventh insulating layer INS7, and the third anode electrode AE3 may be electrically connected to the transistor T_SP3 of the third sub-pixel SP3 through a third via hole VIH3 penetrating the seventh insulating layer INS7.

Each of the first, second, and third anode electrodes AE1, AE2, and AE3 may have a shape similar to the shape of each of the first, second, and third emission areas EMA1, EMA2, and EMA3 of FIG. 5 when viewed from the third direction DR3. For example, the first anode electrode AE1 may have a shape similar to the shape of the first emission area EMA1 when viewed from the third direction DR3, the second anode electrode AE2 may have a shape similar to the shape of of the second emission area EMA2 when viewed from the third direction DR3, and the third anode electrode AE3 may have a shape similar to the shape of the third emission area EMA3 when viewed from the third direction DR3. However, the present disclosure is not limited thereto.

Each of the first to third anode electrodes AE1 to AE3 may be electrically connected to the corresponding pixel circuit PXC and receive a driving current. Each of the first to third anode electrodes AE1 to AE3 may include, but is not limited to, an opaque conductive material capable of reflecting light. According to embodiments, the first to third anode electrodes AE1 to AE3 may include a transparent conductive material.

The pixel defining layer PDL may be located on the first to third anode electrodes AE1 to AE3. The pixel defining layer PDL may include an opening OP exposing a portion of the first anode electrode AE1, a portion of the second anode electrode AE2, and a portion of the third anode electrode AE3. The pixel defining layer PDL may be a structure which defines (or partitions) a light emitting region of each of the first to third sub-pixels SP1 to SP3. For example, the pixel defining layer PDL may define the first emission area EMA1 of the first sub-pixel SP1, the second emission area EMA2 of the second sub-pixel SP2, and the third emission area EMA3 of the third sub-pixel SP3.

The pixel defining layer PDL may include an organic insulating layer including an organic material. The organic material (or an organic substance) may include, for example, acrylic resin, epoxy resin, phenolic resin, polyamide resin, polyimide resin, and the like. According to embodiments, the pixel defining layer PDL may include a light absorbing material, or a light absorber may be applied thereto such that the pixel defining layer PDL may absorb light from an external source. For example, the pixel defining layer PDL may include a carbon-based black pigment of the carbon family. However, the present disclosure is not limited thereto.

A first light emitting layer EML1 may be arranged on the first anode electrode AE1 exposed by the opening OP in the pixel defining layer PDL, and a second light emitting layer EML2 may be arranged on the second anode electrode AE2 exposed by another opening OP in the pixel defining layer PDL, a third light emitting layer EML3 may be arranged on the third anode electrode AE3 exposed by another opening OP of the pixel defining layer PDL. Each of the first to third light emitting layers EML1 to EML3 may have a multilayer structure including a hole injection layer, a hole transport layer, an organic light emitting layer, an electron transport layer, and an electron injection layer.

The first to third light emitting layers EML1 to EML3 may include at least one of the light-emitting materials which emit different colors of light depending on the corresponding sub-pixel SP. For example, the first light emitting layer EML1 may include at least one of the red light emitting materials, the second light emitting layer EML2 may include at least one of the green light emitting materials, and the third light emitting layer EML3 may include at least one of the blue light emitting materials. According to an embodiment, each of the first to third light emitting layers EML1 to EML3 may emit white light as a whole by stacking a plurality of light emitting materials capable of generating different colors of light, such as red light, green light, blue light, and the like. A color filter may be further arranged on each of the first to third light emitting layers EML1 to EML3. The color filter may include at least one of a red color filter, a green color filter, and a blue color filter.

The cathode electrode CE may be arranged on the first to third emission layers EML1 to EML3 and the pixel defining layer PDL. The cathode electrode CE may be a common layer which is provided in common to the first to third sub-pixels SP1 to SP3. The cathode electrode CE may be provided in the form of a plate across the entire area of the display area DA. According to embodiments, the cathode electrode CE may function as a half mirror which partially transmits and partially reflects light emitted from the corresponding light emitting layer.

The cathode electrode CE may be a thin metal layer which is thick enough to transmit the light emitted from the corresponding light emitting layer. The cathode electrode CE may include a metallic material to have a relatively small thickness or may include a transparent conductive material. In embodiments, the cathode electrode CE may include at least one of various transparent conductive materials, including indium tin oxide, indium zinc oxide, indium tin zinc oxide, aluminum zinc oxide, gallium zinc oxide, zinc tin oxide, or gallium tin oxide as well as one or more combinations thereof. In other embodiments, the cathode electrode CE may include at least one of magnesium, silver, and mixtures thereof. However, the material of the cathode electrode CE is not limited to the above-described embodiments.

The first anode electrode AE1, the first light emitting layer EML1, and the portion of the cathode electrode CE overlapping the first anode electrode AE1 in a plan view may constitute the first light-emitting element LED1. The second anode electrode AE2, the second light emitting layer EML2, and the portion of the cathode electrode CE overlapping the second anode electrode AE2 may constitute the second light-emitting element LED2. The third anode electrode AE3, the third light emitting layer EML3, and the portion of the cathode electrode CE overlapping the third anode electrode AE3 may constitute the third light-emitting element LED3.

The thin film encapsulation layer TFE may be arranged on the cathode electrode CE. The thin film encapsulation layer TFE may cover the display element layer DPL. The thin film encapsulation layer TFE may be configured to prevent oxygen and/or moisture from permeating into the display element layer DPL. In embodiments, the thin film encapsulation layer TFE may include a structure of one or more inorganic layers stacked alternately with one or more organic layers. For example, the inorganic layers may include silicon nitride, silicon oxide, or silicon oxynitride as well as one or more combinations thereof. For example, the organic layer may include an organic insulating material such as an acrylic resin, an epoxy resin, a phenolic resin, a polyamide resin, a polyimide resin, an unsaturated polyester resin, a polyphenylene resin, a polyphenylene sulfide resin, or benzocyclobutene as well as one or more combinations thereof. However, the materials of the organic and inorganic layers of the thin film encapsulation layer TFE are not limited thereto.

A touch sensor layer TS may be arranged on the thin film encapsulation layer TFE. The touch sensor layer TS may be arranged directly on the thin film encapsulation layer TFE.

The touch sensor layer TS may be arranged on a surface of the display device DD on which an image is projected and may receive touch input from a user. The touch sensor layer TS may recognize a touch event of the display device DD through a user's hand, a separate input unit, or the like. For example, the touch sensor layer TS may recognize the touch event in a capacitive manner.

The window WD may be arranged on the touch sensor layer TS. The window WD may be a protective member arranged on top of the touch sensor layer TS to protect the configuration of the display device DD. The window WD may be glass or plastic. When the window WD includes glass, ultra-thin glass (UTG) having a thickness of 0.1 mm or less may be applicable in order to obtain flexibility. However, the present disclosure is not limited thereto.

According to embodiments, the display device DD may further include a polarizing layer POL arranged between the touch sensor TS and the window WD. The polarizing layer POL may serve to reduce external light reflection. The polarizing layer POL may be coupled to the window WD using an optically clear adhesive member or the like.

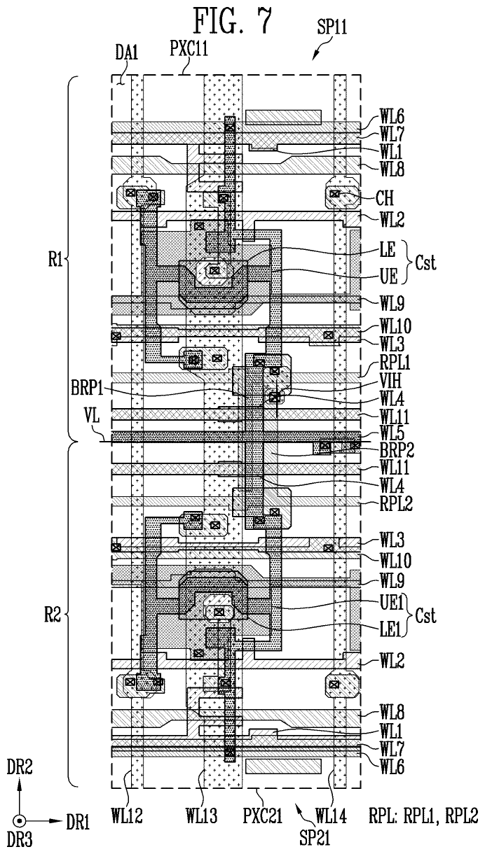

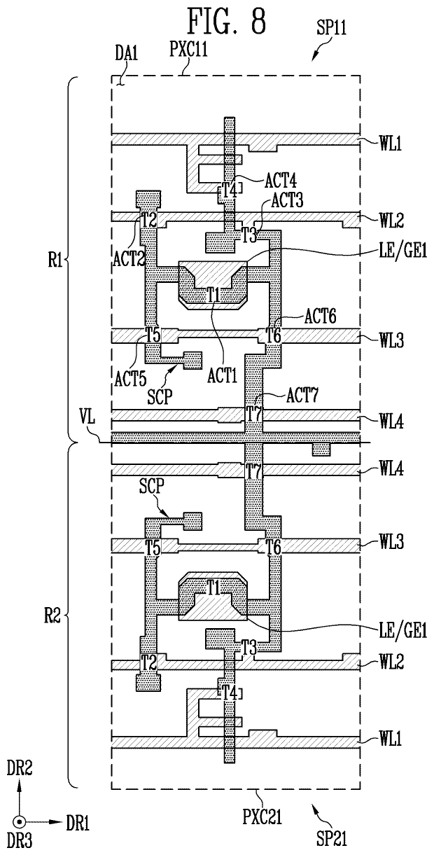

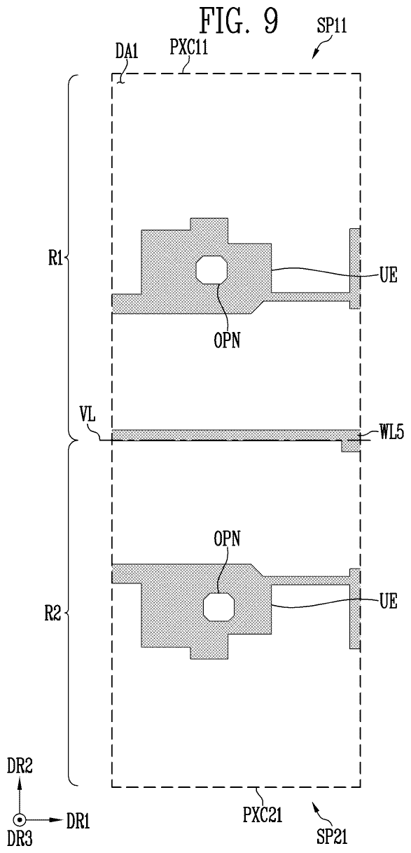

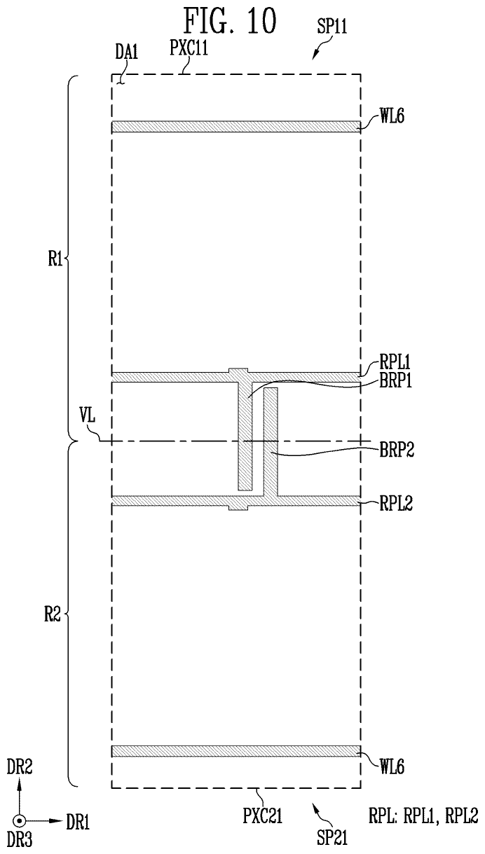

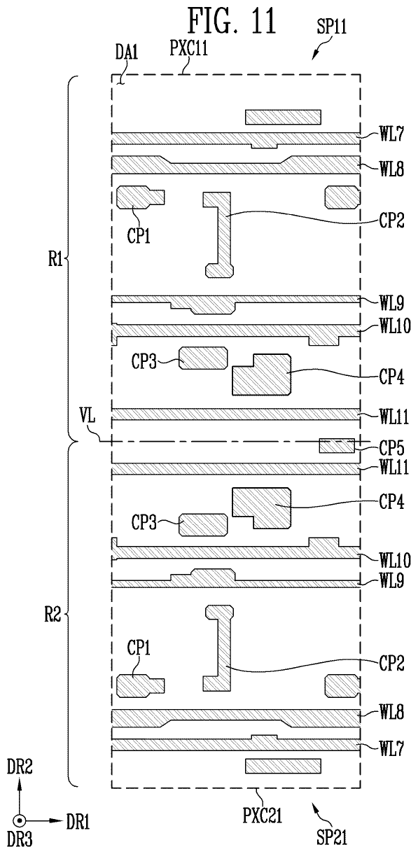

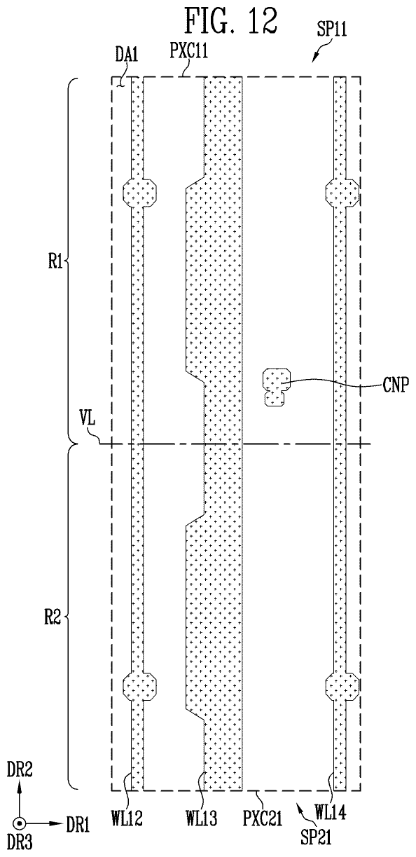

FIG. 7 is a schematic plan view illustrating sub-pixels arranged in a first row R1 and a second row R2 located in a portion of the first area DA1 of a display area of a display device according to one embodiment. FIG. 8 is a schematic plan view illustrating only the configurations included in the first to seventh transistors T1 to T7 and the first conductive layer in FIG. 7. FIG. 9 is a schematic plan view of only the configurations included in the second conductive layer of FIG. 7. FIG. 10 is a schematic plan view of only the configurations included in the third conductive layer of FIG. 7. FIG. 11 is a schematic plan view of only the configurations included in the fourth conductive layer of FIG. 7. FIG. 12 is a schematic plan view of only the configurations included in the fifth conductive layer of FIG. 7.

Differences from the above-described embodiments are described below with reference to FIGS. 7 to 12 so as to avoid redundancy.

Referring to FIGS. 2 and 7 to 12, the sub-pixel (see “SP” in FIG. 2) may be arranged in each of the first row R1 (or a first pixel row) and the second row R2 (or a second pixel row) located in the same column in the second direction DR2 in the first area DA1 (or the first display area). For example, an 11th sub-pixel SP11 (or the first sub-pixel) may be arranged in the first row R1, and a 21st sub-pixel SP21 (or the first sub-pixel) may be arranged in the second row R2. The 11th sub-pixel SP11 may include an 11th pixel circuit PXC11, and the 21st sub-pixel SP21 may include a 21st pixel circuit PXC21.

In an embodiment, the 11th pixel circuit PXC11 and the 21st pixel circuit PXC21 are arranged in the second direction DR2 and may face each other with respect to the repair line RPL. For example, the 11th pixel circuit PXC11 and the 21st pixel circuit PXC21 may be mutually symmetrical and substantially identical with respect to the repair line RPL. The 11th pixel circuit PXC11 and the 21st pixel circuit PXC21 may be mirror symmetrical with respect to the repair line RPL.

Signal lines may be arranged in the first area DA1 where the 11th sub-pixel SP11 and the 21st sub-pixel SP21 are located. For example, first to fourteenth wiring lines WL1 to WL14 may be arranged in the first area DA1.

The first wiring line WL1 may extend in the first direction DR1 and may include a first conductive layer arranged between the second insulating layer (see “INS2” in FIG. 6) and the third insulating layer (see “INS3” in FIG. 6). The first wiring line WL1 may be the 2i-th scan line S2i as described above with reference to FIG. 3. One region of the first wiring line WL1 may be the gate electrode of the fourth transistor T4 of each of the 11th and 21st pixel circuits PXC11 and PXC21 (hereinafter, referred to as a “fourth gate electrode”).

A second wiring line WL2 may extend in the first direction DR1 and be spaced apart from the first wiring line WL1. The second wiring line WL2 may include a first conductive layer. The second wiring line WL2 may be the 1i-th scan line S1i as described above with reference to FIG. 3. One region of the second wiring line WL2 may be the gate electrode (hereinafter, referred to as a “second gate electrode”) of the second transistor T2 of each of the 11th and 21st pixel circuits PXC11 and PXC21. Further, another area of the second wiring line WL2 may be the gate electrode of the third transistor T3 of each of the 11th and 21st pixel circuits PXC11 and PXC21 (hereinafter, referred to as a “third gate electrode”).

A third wiring line WL3 may extend in the first direction DR1 and be spaced apart from the first and second wiring lines WL1 and WL2. The third wiring line WL3 may include a first conductive layer. The third wiring line WL3 may be the i-th emission control line Ei as described with reference to FIG. 3. A region of the third wiring line WL3 may be the gate electrode of the fifth transistor T5 of each of the 11th and 21st pixel circuits PXC11 and PXC21 (hereinafter, referred to as a “fifth gate electrode”). In addition, another area of the third wiring line WL3 may be the gate electrode of the sixth transistor T6 of each of the 11th and 21st pixel circuits PXC11 and PXC21 (hereinafter, referred to as a “sixth gate electrode”).

A fourth wiring line WL4 may extend in the first direction DR1 and be spaced apart from the first to third wiring lines WL1 through WL3. The fourth wiring line WL4 may include a first conductive layer. The fourth wiring line WL4 may be the 3i-th scan line S3i as described with reference to FIG. 3. One region of the fourth wiring line WL4 may be the gate electrode of the seventh transistor T7 of each of the 11th and 21st pixel circuits PXC11 and PXC21 (hereinafter, referred to as a “seventh gate electrode”).

A fifth wiring line WL5 extends in the first direction DR1 and may include a second conductive layer arranged between the third insulating layer INS3 and the fourth insulating layer (see “INS4” in FIG. 6). The fifth wiring line WL5 may be the fourth power line PL4 described with reference to FIG. 3.

A sixth wiring line WL6 extends in the first direction DR1 and may include a third conductive layer arranged between the fourth insulating layer INS4 and the fifth insulating layer (see “INS5” in FIG. 6). The sixth wiring line WL6 may be the second power line PL2 as described with reference to FIG. 3.

A seventh wiring line WL7 extends in the first direction DR1 and may include a fourth conductive layer arranged between the fifth insulating layer INS5 and the sixth insulating layer (see “INS6” in FIG. 6). The seventh wiring line WL7 may be, but is not limited to, a dummy line overlapping the first wiring line WL1 including the first conductive layer. According to an embodiment, the seventh wiring line WL7 may be electrically connected to the first wiring line WL1 to realize the first wiring line WL1 as a dual structure.

An eighth wiring line WL8 may extend in the first direction DR1 and be spaced apart from the seventh wiring line WL7. The eighth wiring line WL8 may include a fourth conductive layer. The eighth wiring line WL8 may be a dummy line. In an embodiment, the eighth wiring line WL8 may be electrically connected to the second wiring line WL2 including the first conductive layer, thereby realizing the second wiring line WL2 as a dual structure.

The ninth wiring line WL9 may extend in the first direction DR1 and be spaced apart from the seventh and eighth wiring lines WL7 and WL8. The ninth wiring line WL9 may include a fourth conductive layer. The ninth wiring line WL9 may be the first power line PL1 as described with reference to FIG. 3.

A tenth wiring line WL10 may extend in the first direction DR1 and be spaced apart from the seventh through ninth wiring lines WL7 through WL9. The tenth wiring line WL10 may include a fourth conductive layer. The tenth wiring line WL10 may be a dummy line overlapping the third wiring line WL3 including the first conductive layer in a plan view. According to an embodiment, the tenth wiring line WL10 may be electrically connected to the third wiring line WL3 to realize the third wiring line WL3 as a dual structure.

An eleventh wiring line WL11 may extend in the first direction DR1 and be spaced apart from the seventh through tenth wiring lines WL7 to WL10. The eleventh wiring line WL11 may include a fourth conductive layer. The eleventh wiring line WL11 may be a dummy line overlapping the fourth wiring line WL4 including the first conductive layer. According to an embodiment, the eleventh wiring line WL11 may be electrically connected to the fourth wiring line WL4 through the corresponding contact hole CH to realize the fourth wiring line WL4 as a dual structure.

A twelfth wiring line WL12 may extend in the second direction DR2 crossing the first direction DR1 and may include a fifth conductive layer arranged between the sixth insulating layer INS6 and the seventh insulating layer (see “INS7” in FIG. 6). The twelfth wiring line WL12 may be the j-th data line Dj as described with reference to FIG. 3. The twelfth wiring line WL12 may be electrically connected to the second transistor T2 of each of the 11th and 21st pixel circuits PXC11 and PXC21 through a first conductive pattern CP1.

The first conductive pattern CP1 may include a fourth conductive layer. The first conductive pattern CP1 may be electrically connected to the twelfth wiring line WL12 through the contact hole CH passing through the sixth insulating layer INS6. Further, the first conductive pattern CP1 may be electrically connected to the semiconductor pattern SCP of the second transistor T2 of each of the 11th and 21st pixel circuits PXC11 and PXC21 through the contact hole CH passing through the fifth insulating layer INS5, the fourth insulating layer INS4, the third insulating layer INS3, and the second insulating layer INS2.

A thirteenth wiring line WL13 may extend in the second direction DR2 and may be spaced apart from the twelfth wiring line WL12. The thirteenth wiring line WL13 may include a fifth conductive layer. The thirteenth wiring line WL13 may be electrically connected to the fifth transistor T5 of each of the 11th and 21st pixel circuits PXC11 and PXC21 through a third conductive pattern CP3.

The third conductive pattern CP3 may include a fourth conductive layer. The third conductive pattern CP3 may be electrically connected to the thirteenth wiring line WL13 through the contact hole CH passing through the sixth insulating layer INS6. Further, the third conductive pattern CP3 may be electrically connected to the semiconductor pattern SCP of the fifth transistor T5 of each of the 11th and 21st pixel circuits PXC11 and PXC21 through the contact hole CH which penetrates the fifth insulating layer INS5, the fourth insulating layer INS4, the third insulating layer INS3, and the second insulating layer INS2.

The thirteenth wiring line WL13 may be the first power line PL1 as described with reference to FIG. 3. The thirteenth wiring line WL13 may be a vertical power line of the first power line PL1, and the ninth wiring line WL9 may be a horizontal power line of the first power line PL1. The ninth wiring line WL9 and the thirteenth wiring line WL13 may be electrically connected to each other to form a mesh structure of the first power line PL1.

The fourteenth wiring line WL14 extends in the second direction DR2 and is spaced apart from the twelfth and thirteenth wiring lines WL12 and WL13. The fourteenth wiring line WL14 may include a fifth conductive layer. The fourteenth wiring line WL14 may be a (j+1)th data line adjacent to the j-th data line Dj.

The connection pattern CNP may be arranged between the thirteenth wiring line WL13 and 14th wiring line WL14. The connection pattern CNP may include a fifth conductive layer. The connection pattern CNP may be the connection line CNL described with reference to FIG. 6. The connection pattern CNP may be electrically connected to a corresponding anode electrode (see “AE” in FIG. 3) of the corresponding light-emitting element (see “LED” in FIG. 3) through a via hole VIH passing through the seventh insulating layer INS7. Further, the connection pattern CNP may be electrically connected to a fourth conductive pattern CP4 through the contact hole CH passing through the sixth insulating layer INS6.

The 11th pixel circuit PXC11 and the 21st pixel circuit PXC21 may have substantially similar or identical structures. For example, the 11th pixel circuit PXC11 and the 21st pixel circuit PXC21 may be mirror symmetrical based on an imaginary line VL extending in the first direction DR1 between the first row R1 and the second row R2. Hereinafter, for convenience, a description will be mainly made based on the 11th pixel circuit PXC11 and an overlapping description will be omitted.

The 11th pixel circuit PXC11 may include the first, second, third, fourth, fifth, sixth, and seventh transistors T1, T2, T3, T4, T5, T6, and T7 and the storage capacitor Cst.

The first transistor T1 may include a first active pattern ACT1 and a first gate electrode GE1.

The first active pattern ACT1 may be a region of the semiconductor pattern SCP which overlaps the first gate electrode GE1 in a plan view. The first active pattern ACT1 may be a channel region of the first transistor T1.

A region of the semiconductor pattern SCP which does not overlap the first gate electrode GE1 and is connected to one side of the first active pattern ACT1 (e.g., the left side of the first active pattern ACT1 in the plan view) may be a first input/output terminal. A region of the semiconductor pattern SCP which does not overlap the first gate electrode GE1 and is connected to the other side of the first active pattern ACT1 (e.g., the right side of the first active pattern ACT1 in the plan view) may be a second input/output terminal. The first input/output terminal may be connected to each of one side of the first active pattern ACT1, the semiconductor pattern SCP of the second transistor T2, and the semiconductor pattern SCP of the fifth transistor T5. The second input/output terminal may be connected to the other side of the first active pattern ACT1 and may be connected to the semiconductor pattern SCP of the sixth transistor T6.

The first gate electrode GE1 overlaps the first active pattern ACT1 in a plan view and may include a first conductive layer. The first gate electrode GE1 may be an island-shaped conductive pattern. The first gate electrode GE1 may be electrically connected to the third transistor T3 and the fourth transistor T4 through a second conductive pattern CP2.

The second conductive pattern CP2 may include a fourth conductive layer. One end of the second conductive pattern CP2 may be electrically connected to the first gate electrode GE1 through the contact hole CH passing through the fifth insulating layer INS5, the fourth insulating layer INS4, and the third insulating layer INS3. The other end of the second conductive pattern CP2 may be electrically connected to a region of the semiconductor pattern SCP shared by the third transistor T3 and the fourth transistor T4 through the contact hole CH passing through the fifth insulating layer INS5, the fourth insulating layer INS4, the third insulating layer INS3, and the second insulating layer INS2.

The second transistor T2 may include a second active pattern ACT2 and a second gate electrode.

The second active pattern ACT2 may be a region of the semiconductor pattern SCP which overlaps the second wiring line WL2. The second active pattern ACT2 may be a channel region of the second transistor T2.

A region of the semiconductor pattern SCP which does not overlap the second wiring line WL2 in a plan view and is connected to one side of the second active pattern ACT2 (e.g., the upper side of the second active pattern ACT2 in the plan view) may be a first input/output terminal. A region of the semiconductor pattern SCP which does not overlap the second wiring line WL2 and is connected to the other side of the second active pattern ACT2 (e.g., the lower side of the second active pattern ACT2 in the plan view) may be a second input/output terminal. The first input/output terminal may be connected to one side of the second active pattern ACT2 and may be electrically connected to the first conductive pattern CP1. The first input/output terminal may be electrically connected to the twelfth wiring line WL12 (or data line) through the first conductive pattern CP1. The second input/output terminal may be connected to the other side of the second active pattern ACT2, and may be connected to the first input/output terminal of the first transistor T1.

The second gate electrode may be a region of the second wiring line WL2 which overlaps the second active pattern ACT2 in a plan view.

The third transistor T3 may be configured in which sub-transistors are connected in series to prevent leakage current. For convenience of description, the third transistor T3 formed on the protrusion of the second wiring line WL2 among the above sub-transistors will be described as a representative example.

The third transistor T3 may include a third active pattern ACT3 and a third gate electrode.

The third active pattern ACT3 is a region of the semiconductor pattern SCP which overlaps a protrusion projecting from the second wiring line WL2 in the second direction DR2, and may form a channel region of the third transistor T3.

A region of the semiconductor pattern SCP which does not overlap the second wiring line WL2 in a plan view and is connected to one side of the third active pattern ACT3 (e.g., the right side of the third active pattern ACT3 in the plan view) may be a first input/output terminal. A region of the semiconductor pattern SCP which does not overlap the second wiring line WL2 in a plan view and is connected to the other side of the third active pattern ACT3 (e.g., the left side of the third active pattern ACT3 in the plan view) may be a second input/output terminal. The first input/output terminal may be connected to one side of the third active pattern ACT3 and may be electrically connected to the semiconductor pattern SCP of the first and sixth transistors T1 and T6. The second input/output terminal may be connected to the other side of the third active pattern ACT3 and electrically coupled to the semiconductor pattern SCP of the fourth transistor T4.

The third gate electrode may be a region of the second wiring line WL2 which overlaps the third active pattern ACT3 in a plan view.

The fourth transistor T4 may be configured with sub-transistors connected in series to prevent leakage current. For convenience of description, the fourth transistor T4, which is arranged closest to the third transistor T3 among the above sub-transistors, will be described as a representative example.

The fourth transistor T4 may include a fourth active pattern ACT4 and a fourth gate electrode.

The fourth active pattern ACT4 is a region of the semiconductor pattern SCP which overlaps the first wiring line WL1, and may form a channel region of the fourth transistor T4.

A region of the semiconductor pattern SCP which does not overlap the first wiring line WL1 and is connected to one side of the fourth active pattern ACT4 (e.g., the lower side of the fourth active pattern ACT4 in the plan view) may be a first input/output terminal. A region of the semiconductor pattern SCP which does not overlap the first wiring line WL1 in a plan view and is connected to the other side of the fourth active pattern ACT4 (e.g., the upper side of the fourth active pattern ACT4 in the plan view) may be a second input/output terminal. The first input/output terminal may be connected to one side of the fourth active pattern ACT4 and may be connected to the semiconductor pattern SCP of the third transistor T3. The second input/output terminal may be connected to the other side of the fourth active pattern ACT4 and electrically connected to the sixth wiring line WL6 through the contact hole CH passing through the fourth insulating layer INS4, the third insulating layer INS3, and the second insulating layer INS2.

The fourth gate electrode may be a region of the first wiring line WL1 which overlaps the fourth active pattern ACT4.

The fifth transistor T5 may include a fifth active pattern ACT5 and a fifth gate electrode.

The fifth active pattern ACT5 is a region of the semiconductor pattern SCP which overlaps the third wiring line WL3 in a plan view, and may form a channel region of the fifth transistor T5.

A region of the semiconductor pattern SCP which does not overlap the third wiring line WL3 and is connected to one side of the fifth active pattern ACT5 (e.g., the lower side of the fifth active pattern ACT5 in the plan view may be a first input/output terminal. A region of the semiconductor pattern SCP which does not overlap the third wiring line WL3 in a plan view and is connected to the other side of the fifth active pattern ACT5 (e.g., the upper side of the fifth active pattern ACT5 in the plan view) may be a second input/output terminal. The first input/output terminal may be connected to one side of the fifth active pattern ACT5 and electrically connected to the first conductive pattern CP1 through the corresponding contact hole CH. The second input/output terminal may be connected to the other side of the fifth active pattern ACT5 and may be connected to the semiconductor pattern SCP of each of the first and second transistors T1 and T2.

The sixth transistor T6 may include a sixth active pattern ACT6 and a sixth gate electrode.

The sixth active pattern ACT6 is a region of the semiconductor pattern SCP which overlaps the third wiring line WL3 in a plan view, and may be a channel region of the sixth transistor T6.

A region of the semiconductor pattern SCP which does not overlap the third wiring line WL3 and is connected to one side of the sixth active pattern ACT6 (e.g., the upper side of the sixth active pattern ACT6 in the plan view) may be a first input/output terminal. A region of the semiconductor pattern SCP which does not overlap the third wiring line WL3 and is connected to the other side of the sixth active pattern ACT6 (e.g., the lower side of the sixth active pattern ACT6 in a plan view) may be a second input/output terminal. The first input/output terminal may be connected to one side of the sixth active pattern ACT6 and the semiconductor pattern SCP of the first transistor T1. The second input/output terminal may be connected to the other side of the sixth active pattern ACT6 and the semiconductor pattern SCP of the seventh transistor T7. Further, the second input/output terminal may be electrically connected to the fourth conductive pattern CP4 through the corresponding contact hole CH.

The fourth conductive pattern CP4 (or the first contact electrode CNE1) may include a fourth conductive layer. The fourth conductive pattern CP4 may be electrically connected to a second input/output terminal of the sixth transistor T6 through the contact hole CH passing through the fifth insulating layer INS5, the fourth insulating layer INS4, the third insulating layer INS3, and the second insulating layer INS2. Further, the fourth conductive pattern CP4 may be electrically connected to the connection pattern CNP through the corresponding contact hole CH. The second input/output terminal of the sixth transistor T6 may be electrically connected to the anode electrode AE of the light-emitting element LED through the fourth conductive pattern CP4 and the connection pattern CNP.

The sixth gate electrode may be a region of the third wiring line WL3 which overlaps the sixth active pattern ACT6 in a plan view.

The seventh transistor T7 may include a seventh active pattern ACT7 and a seventh gate electrode.

The seventh active pattern ACT7 is a region of the semiconductor pattern SCP which overlaps the fourth wiring line WL4, and may be a channel region of the seventh transistor T7.

A region of the semiconductor pattern SCP which does not overlap the fourth wiring line WL4 and is connected to one side of the seventh active pattern ACT7 (e.g., the upper side of the seventh active pattern ACT7 in the plan view) may be a first input/output terminal. A region of the semiconductor pattern SCP which does not overlap the fourth wiring line WL4 in a plan view and is connected to the other side of the seventh active pattern ACT7 (e.g., the lower side of the seventh active pattern ACT7 in the plan view) may be a second input/output terminal. The first input/output terminal may be connected to one side of the seventh active pattern ACT7 and the semiconductor pattern SCPs of the sixth transistor T6. The second input/output terminal may be connected to the other side of the seventh active pattern ACT7 and a fifth conductive pattern CP5.

The fifth conductive pattern CP5 may include a fourth conductive layer. The fifth conductive pattern CP5 may be electrically connected to the semiconductor pattern SCP of the seventh transistor T7 through the contact hole CH passing through the fifth insulating layer INS5, the fourth insulating layer INS4, the third insulating layer INS3, and the second insulating layer INS2. Further, the fifth conductive pattern CP5 may be connected to the fifth wiring line WL5 through the contact hole CH passing through the fifth insulating layer INS5 and the fourth insulating layer INS4.

The seventh gate electrode may be a region of the fourth wiring line WL4 which overlaps the seventh active pattern ACT7.

The storage capacitor Cst may include a lower electrode LE and an upper electrode UE.

The lower electrode LE may be integrally formed with the first gate electrode GE1. The lower electrode LE may include a first conductive layer.

The upper electrode UE overlaps the lower electrode LE in a plan view and may include a second conductive layer. The upper electrode UE may include an opening area OPN by removing a portion thereof. A region of the lower electrode LE overlapping the upper electrode UE in a plan view may be exposed by the opening area OPN. The upper electrode UE may be electrically connected to the thirteenth wiring line WL13 through the contact hole CH which sequentially penetrates the sixth insulating layer INS6, the fifth insulating layer INS5, and the fourth insulating layer INS4.

In the first area DA1, the repair lines RPL may be arranged between the first row R1 and the second row R2. The repair lines RPL may include the first repair line RPL1 and the second repair line RPL2 spaced apart relative to the imaginary line VL extending in the first direction DR1. The first repair line RPL1 may be located above the imaginary line VL and the second repair line RPL2 may be located below the imaginary line VL. The first repair line RPL1 and the second repair line RPL2 may be spaced apart from each other and may be electrically isolated from each other.

The first and second repair lines RPL1 and RPL2 may extend in the first direction DR1. The first and second repair lines RPL1 and RPL2 may include a third conductive layer. The first and second repair lines RPL1 and RPL2 may be formed by the same process as the sixth wiring line WL6. The first and second repair lines RPL1 and RPL2 may be arranged in the same layer as the sixth wiring line WL6 and may include the same material as the sixth wiring line WL6.

The first repair line RPL1 may be electrically connected to a first bridge pattern BRP1. The first bridge pattern BRP1 may be integrally formed with the first repair line RPL1. The first bridge pattern BRP1 may extend in the second direction DR2 and may protrude from the first repair line RPL1 in a direction toward the second repair line (or the second row R2). In an embodiment, the first repair line RPL1 may be electrically connected to one of the first and second dummy pixels (see “DP1 and DP2” in FIG. 2) arranged in each of the first and second rows R1 and R2 of the first non-display area (see “NDA1” in FIG. 2) adjacent to the first area DA1.

The second repair line RPL2 may be electrically connected to a second bridge pattern BRP2. The second bridge pattern BRP2 may be integrally formed with the second repair line RPL2. The second bridge pattern BRP2 may extend in the second direction DR2 and may protrude from the second repair line RPL2 in a direction toward the first repair line RPL1 or the first row R1. In embodiments, the second repair line RPL2 may be electrically connected to the other dummy pixel between the first and second dummy pixels DP1 and DP2 arranged in each of the first and second rows R1 and R2 of the first non-display area NDA1.

The first bridge pattern BRP1 and the second bridge pattern BRP2 are spaced apart and face each other in the first direction DR1. The first bridge pattern BRP1 and the first repair line RPL1 may be electrically isolated from the second bridge pattern BRP2 and the second repair line RPL2, respectively.

The fourth conductive pattern CP4 (or the first contact electrode CNE1) and the connection pattern CNP may be located at a connection point (or the fourth node (see “N4” in FIG. 3)) electrically connecting the anode electrode AE of the 11th sub-pixel SP11 and the 11th pixel circuit PXC11. Further, the semiconductor pattern SCP of each of the sixth transistors T6 and T7 electrically connected to the fourth conductive pattern CP4 may be located at the connection point. The fourth conductive pattern CP4 may be electrically connected to the semiconductor pattern SCP of the sixth transistor T6 through the contact hole CH passing through the fifth insulating layer INS5, the fourth insulating layer INS4, the third insulating layer INS3, and the second insulating layer INS2.

In an embodiment, one end of each of the first and second bridge patterns BRP1 and BRP2 disposed between the first row R1 and the second row R2 may overlap the fourth conductive pattern CP4 of the 11th sub-pixel SP11 of the first row R1, and the other end of each of the first and second bridge patterns BRP1 and BRP2 may overlap the fourth conductive pattern CP4 of the 21st sub-pixel SP21 of the second row R2.

The corresponding repair line RPL between the first and second repair lines RPL1 and RPL2, the first bridge pattern BRP1, and the second bridge pattern BRP2 may overlap the fourth conductive pattern CP4 of each of the 11th and 21st sub-pixels SP11 and SP21. The first and second repair lines RPL1 and RPL2, the first bridge pattern BRP1, and the second bridge pattern BRP2 may be electrically isolated from the fourth conductive pattern CP4.

When a dark spot failure occurs in the 11th sub-pixel SP11, the electrical connection between the semiconductor pattern SCP shared by the sixth transistor T6 and the seventh transistor T7 of the 11th sub-pixel SP11 and the anode electrode AE of the light-emitting element (see “LED” in FIG. 3) may be disconnected, and the fourth conductive pattern CP4 and the first bridge pattern BRP1 of the 11th sub-pixel SP11 may be electrically connected to each other, whereby the light-emitting element LED of the 11th sub-pixel SP11 may operate normally.

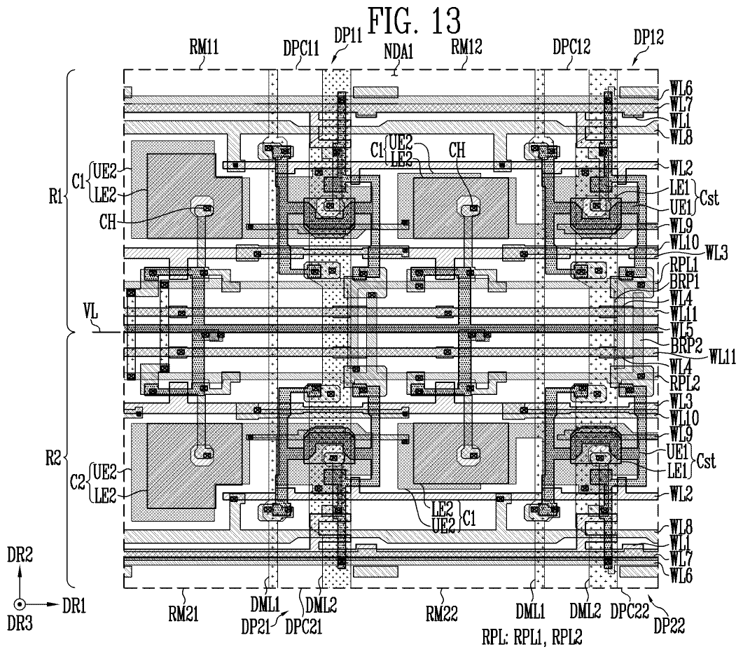

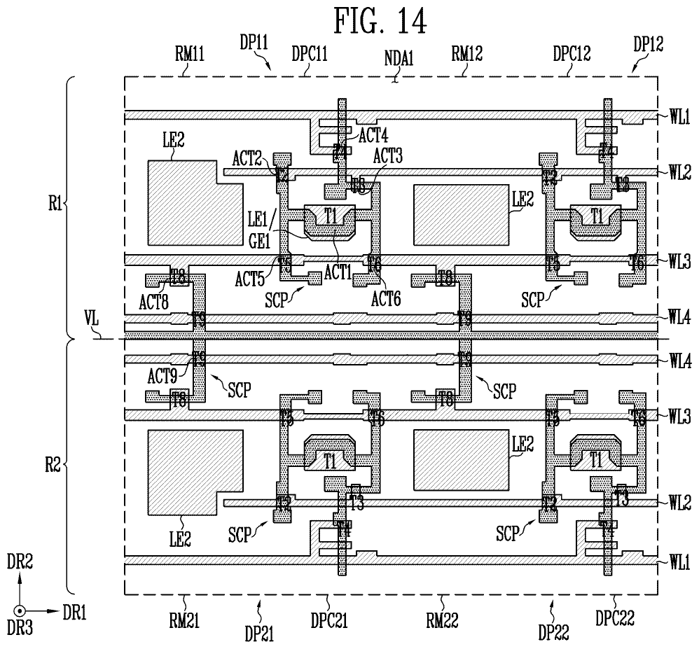

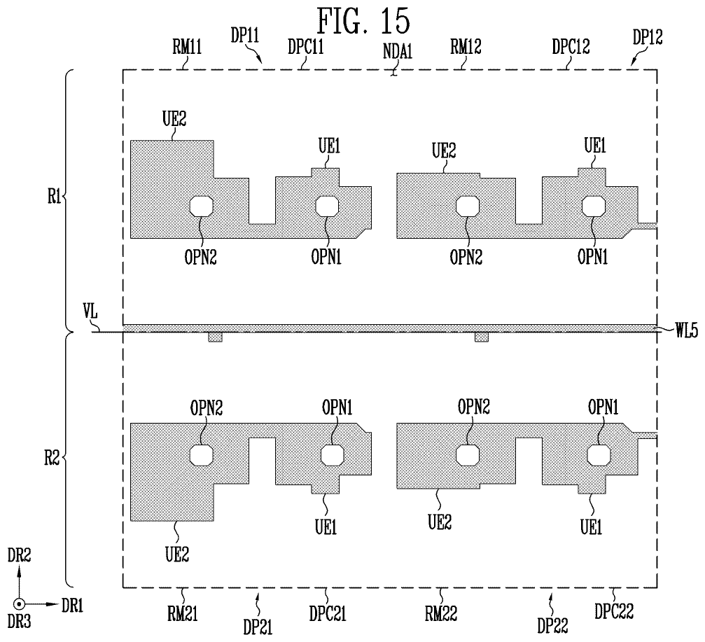

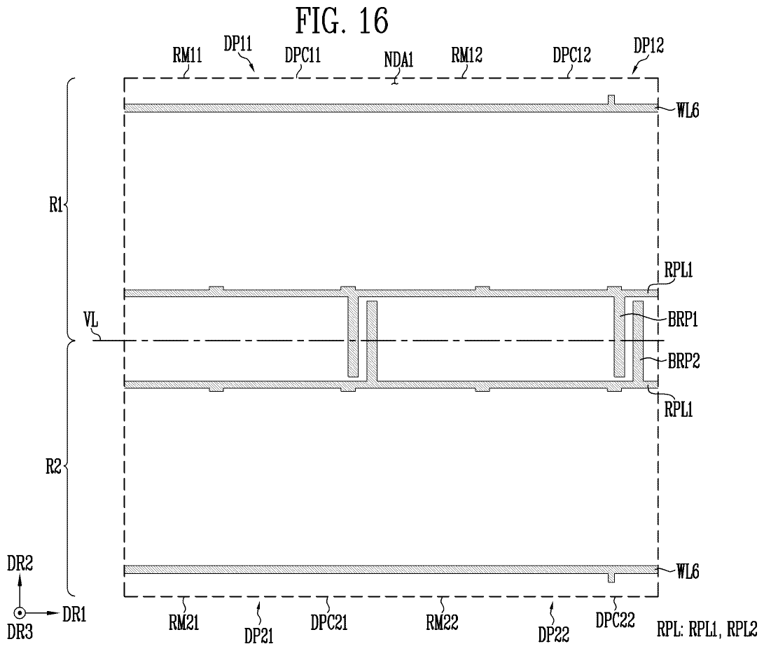

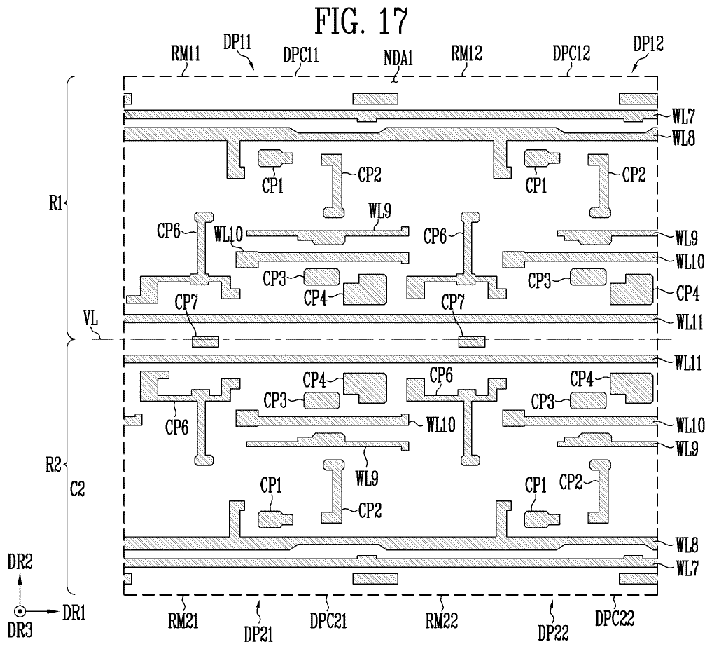

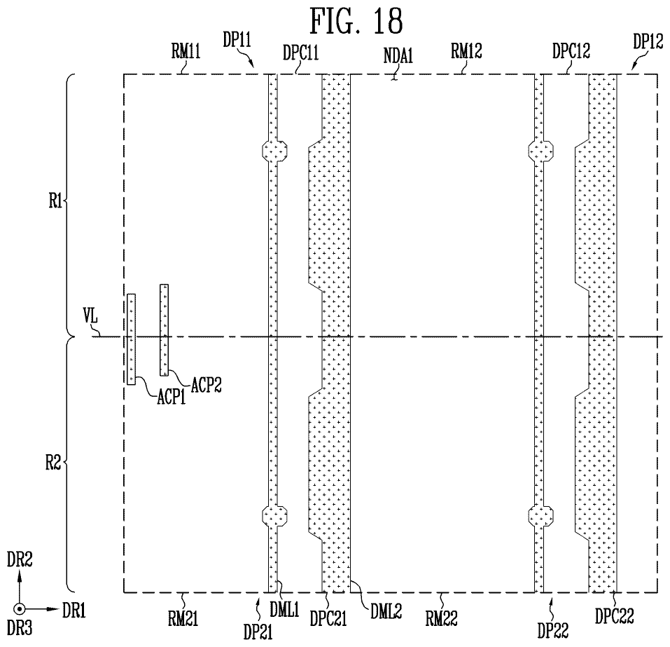

FIG. 13 is a schematic plan view illustrating dummy pixels arranged in the first row R1 and the second row R2 located in one region of the first non-display area NDA1 of the display device according to one embodiment. FIG. 14 is a schematic plan view illustrating only the configurations included in the first to sixth transistors T1 to T6, the eighth and ninth transistors T8 and T9, and the first conductive layer in FIG. 13. FIG. 15 is a schematic plan view of only the configurations included in the second conductive layer of FIG. 13. FIG. 16 is a schematic plan view of only the configurations included in the third conductive layer of FIG. 13. FIG. 17 is a schematic plan view of only the configurations included in the fourth conductive layer of FIG. 13. FIG. 18 is a schematic plan view of only the configurations included in the fifth conductive layer of FIG. 13.

Differences from the above-described embodiments will be mainly described with reference to FIGS. 13 to 18 so as to avoid redundant descriptions.

Referring to FIGS. 2, 4, and 13 to 18, the dummy pixels (see “DP” in FIG. 2) may be arranged in each of the first row R1 and the second row R2 located in the same column in the second direction DR2 in the first non-display area NDA1. For example, an 11th dummy pixel DP11 (or a first dummy pixel) and a 12th dummy pixel DP12 (or a second dummy pixel) may be arranged in the first row R1, and a 21th dummy pixel DP21 (or a first dummy pixel) and a 22nd dummy pixel DP22 (or a second dummy pixel) may be arranged in the second row R2. The 11th dummy pixel DP11 and the 12th dummy pixel DP12 may be adjacent to one another in the first direction DR1, and the 21st dummy pixel DP21 and the 22nd dummy pixel DP22 may be adjacent to one another in the first direction DR1. The 11th dummy pixel DP11 in the first row R1 and the 21st dummy pixel DP21 in the second row R2 may be located in the same column, and the 12th dummy pixel DP12 in the first row R1 and the 22nd dummy pixel DP22 in the second row R2 may be located in the same column.

The 11th and 12th dummy pixels DP11 and DP12 may be arranged in the same row (e.g., the first row R1) as the 11th sub-pixel SP11 as described with reference to FIG. 7. The 21st and 22nd dummy pixels DP21 and DP22 may be arranged in the same row (e.g., the second row R2) as the 21st sub-pixel SP21 as described with reference to FIG. 7. The 12th dummy pixel DP12 may be immediately adjacent to the 11th sub-pixel SP11, and the 22nd dummy pixel DP22 may be immediately adjacent to the 21st sub-pixel SP21. In the first row R1, the 12th dummy pixel DP12 may be located closer to the first area (see “DA1” in FIG. 7) (or the sub-pixels) than the 11th dummy pixel DP11, and in the second row R2, the 22nd dummy pixel DP22 may be located closer to the first area DA1) (or the sub-pixels) than the 21st dummy pixel DP21.

The dummy pixel DP may include a dummy pixel circuit and a repair modulation circuit. For example, the 11th dummy pixel DP11 includes an 11th dummy pixel circuit DPC11 and an 11th repair modulation circuit RM11, and a 12th dummy pixelDP12 includes a 12th dummy pixel circuit DPC12 and a 12th repair modulation circuit RM12, a 21st dummy pixel DP21 includes a 21st dummy pixel circuit DPC21 and a 21st repair modulation circuit RM21, and a 22nd dummy pixel DP22 may include a 22nd dummy pixel circuit DPC22 and a 22nd repair modulation circuit RM22.

In an embodiment, the 11th dummy pixel DP11 and the 21st dummy pixel DP21 are arranged in the second direction DR2 and may face each other with respect to the repair line RPL. The 12th dummy pixel DP12 and the 22nd dummy pixel DP22 are arranged in the second direction DR2 and may face each other with respect to the repair line RPL. The 11th dummy pixel circuit DPC11 and the 21st dummy pixel circuit DPC21 may be mutually symmetrical and substantially identical with respect to the repair line RPL, but are not limited thereto. The 11th dummy pixel circuit DPC11 and the 21st dummy pixel circuit DPC21 may be mirror symmetrical with respect to the repair line RPL. The 12th dummy pixel circuit DPC12 and the 22nd dummy pixel circuit DPC22 may be mirror symmetrical with respect to the repair line RPL.

Signal lines connected to the 11th dummy pixel DP11, the 12th dummy pixel DP12, the 21st dummy pixel DP21, and the 22nd dummy pixel DP22 may be arranged in the first non-display area NDA1. For example, first to eleventh wiring lines WL1 to WL11 may be arranged in the first non-display area NDA1. The first to eleventh wiring lines WL1 to WL11 may be the first to eleventh wiring lines WL1 to WL11 as described with reference to FIG. 7.

Further, two first dummy lines DML1 and two second dummy lines DML2 may be arranged in the first non-display area NDA1. Each of the first dummy lines DML1 extends in the second direction DR2 and may include a fifth conductive layer arranged between the sixth insulating layer (see “INS6” in FIG. 6) and the seventh insulating layer (see “INS7”) in FIG. 6. Each of the first dummy lines DML1 may be the first dummy data line DD1 as described with reference to FIG. 4. Each of the first dummy lines DML1 may be electrically connected to the second transistor T2 of each of the 11th, 12th, 21st, and 22nd dummy pixel circuits DPC11, DPC12, DPC21, and DPC22 through the corresponding first conductive pattern CP1.

Each of the second dummy lines DML2 may extend in the second direction DR2 and may include a fifth conductive layer. Each of the second dummy lines DML2 may be the thirteenth wiring line WL13 as described with reference to FIGS. 7 to 12. Each of the second dummy lines DML2 may be electrically connected to the fifth transistor T5 of each of the 11th, 12th, 21st, and 22nd dummy pixel circuits DPC11 and DPC12, DPC21, and DPC22 through the third conductive pattern CP3.

The 11th, 12th, 21st, and 22nd dummy pixel circuits DPC11, DPC12, DPC21, and DPC22 may have substantially similar or identical structures. Hereinafter, for convenience, a description will be mainly made based on the 11th dummy pixel DP11 and an overlapping description will be omitted.

The 11th dummy pixel DP11 may include the 11th dummy pixel circuit DPC11 and the 11th repair modulation circuit RM11.

The 11th dummy pixel circuit DPC11 may include the first, second, third, fourth, fifth, and sixth transistors T1, T2, T3, T4, T5, and T6, and the storage capacitor Cst. The first to sixth transistors T1 to T6 are identical to the first to sixth transistors T1 to T6 as described with reference to FIGS. 7 to 12, and therefore will not be described herein.

The storage capacitor Cst may include a first lower electrode LE1 and a first upper electrode UE1. The first lower electrode LE1 may be the lower electrode LE as described with reference to FIGS. 7 to 12, and the first upper electrode UE1 may be the upper electrode UE as described with reference to FIGS. 7 to 12. The first upper electrode UE1 may include a first opening area OPN1 by removing one first portion thereof. One region of the first lower electrode LE1 overlapping the first upper electrode UE1 may be exposed by the first opening area OPN1. The first upper electrode UE1 may be electrically connected to the corresponding second dummy line DML2 through the contact hole CH passing through the sixth insulating layer INS6, the fifth insulating layer (see “INS5” in FIG. 6), and the fourth insulating layer (see “INS4”.

The 11th repair modulation circuit RM11 may include the eighth and ninth transistors T8 and T9 and the first capacitor C1.

The eighth transistor T8 may include an eighth active pattern ACT8 and an eighth gate electrode.

The eighth active pattern ACT8 may be a region of the semiconductor pattern SCP which overlaps the third wiring line WL3. The eighth active pattern ACT8 may be a channel region of the eighth transistor T8.

A region of the semiconductor pattern SCP which does not overlap the third wiring line WL3 in a plan view and is connected to one side of the eighth active pattern ACT8 (e.g., the left side of the eighth active pattern ACT8 in the plan view) may be a first input/output terminal. A region of the semiconductor pattern SCP which does not overlap the third wiring line WL3 in a plan view and is connected to the other side of the eighth active pattern ACT8 (e.g., the right side of the eighth active pattern ACT8 in the plan view) may be a second input/output terminal. The first input/output terminal may be connected to one side of the eighth active pattern ACT8 and to a sixth conductive pattern CP6. The second input/output terminal may be connected to the other side of the eighth active pattern ACT8 and the semiconductor pattern SCP of the ninth transistor T9.

The sixth conductive pattern CP6 may include a fourth conductive layer. The sixth conductive pattern CP6 may be electrically connected to the first input/output terminal of the eighth transistor T8 through the contact hole CH passing through the fifth insulating layer INS5, the fourth insulating layer INS4, the third insulating layer (see “INS3” in FIG. 6), and the second insulating layer (see “INS2” in FIG. 6). Further, the sixth conductive pattern CP6 may be electrically connected to an additional conductive pattern ACP1 through the contact hole CH passing through the sixth insulating layer INS6.

The first additional conductive pattern ACP1 may include a fifth conductive layer arranged on the sixth insulating layer INS6. One end of the first additional conductive pattern ACP1 may be electrically connected to the sixth conductive pattern CP6 through the corresponding contact hole CH. The other end of the first additional conductive pattern ACP1 may be electrically connected to the second repair line RPL2 through the contact hole CH passing through the sixth insulating layer INS6, the fifth insulating layer INS5, and the fourth insulating layer INS4. The second repair line RPL2 may be electrically connected to the first input/output terminal of the eighth transistor T8 through the first additional conductive pattern ACP1 and the sixth conductive pattern CP6.

In embodiments, the sixth conductive pattern CP6 may be electrically connected to the second lower electrode LE2 through the contact hole CH passing through the fifth insulating layer INS5, the fourth insulating layer INS4, and the third insulating layer INS3. Further, the sixth conductive pattern CP6 may be electrically connected to the second input/output terminal of the eighth transistor T8 through the contact hole CH passing through the fifth insulating layer INS5, the fourth insulating layer INS4, the third insulating layer INS3, and the second insulating layer INS2. The second input/output terminal of the eighth transistor T8 may be connected to the semiconductor pattern SCP of the ninth transistor T9.

The eight gate electrode may be a region of the third wiring line WL3 which overlaps the eight active pattern ACT8 in a plan view.

The ninth transistor T9 may include a ninth active pattern ACT9 and a ninth gate electrode.

The ninth active pattern ACT9 may be a region of the semiconductor pattern SCP which overlaps the fourth wiring line WL4. The ninth active pattern ACT9 may be a channel region of the ninth transistor T9.

A region of the semiconductor pattern SCP which does not overlap the fourth wiring line WL4 and is connected to one side of the ninth active pattern ACT9 (e.g., the upper side of the ninth active pattern ACT9 in the plan view) may be a first input/output terminal. A region of the semiconductor pattern SCP which does not overlap the fourth wiring line WL4 in a plan view and is connected to the other side of the ninth active pattern ACT9 (e.g., the lower side of the ninth active pattern ACT9 in the plan view) may be a second input/output terminal. The first input/output terminal may be electrically connected to one side of the ninth active pattern ACT9 and the semiconductor pattern SCP of the eighth transistor T8. The second input/output terminal may be electrically connected to the other side of the ninth active pattern ACT9 and a seventh conductive pattern CP7.

The seventh conductive pattern CP7 may include a fourth conductive layer. The seventh conductive pattern CP7 may be electrically connected to the semiconductor pattern SCP of the ninth transistor T9 through the contact hole CH passing through the fifth insulating layer INS5, the fourth insulating layer INS4, the third insulating layer INS3, and the second insulating layer INS2. Further, the seventh conductive pattern CP7 may be electrically connected to the fifth wiring line WL5 through the contact hole CH passing through the fifth insulating layer INS5 and the fourth insulating layer INS4. The first initialization power voltage (see “Vint1” in FIG. 4) may be provided to the fifth wiring line WL5. The fifth wiring line WL5 may be the second power line P2 as described above with reference to FIG. 4 or the fourth power line PL4 as described above with reference to FIG. 3. The fifth wiring line WL5 may be electrically connected to a region of the semiconductor pattern SCP of the ninth transistor T9 (e.g., the second input/output terminal) through the seventh conductive pattern CP7.

The ninth gate electrode may be a region of the fourth wiring line WL4 which overlaps the ninth active pattern ACT9 in a plan view.

The first capacitor C1 may include a second lower electrode LE2 and a second upper electrode UE2.

The second lower electrode LE2 may be spaced apart from the first lower electrode LE1. The second lower electrode LE2 may include a first conductive layer. For example, the second lower electrode LE2 may be formed by the same processes as the first lower electrode LE1 (or the first gate electrode GE1), may be arranged in the same layer as the first lower electrode LE1, and may include the same material as the first lower electrode LE1. The second bottom electrode LE2 may be electrically connected to the semiconductor pattern SCP shared by the eighth transistor T8 and the ninth transistor T9 through the sixth conductive pattern CP6.

The second upper electrode UE2 may include a second conductive layer and overlap the second lower electrode LE2 while interposing the third insulating layer INS3. The second upper electrode UE2 may include a second opening area OPN2 by removing a portion thereof. One region of the second lower electrode LE2 overlapping the second upper electrode UE2 in a plan view may be exposed by the second opening area OPN2. The second upper electrode UE2 may be integrally formed with the first upper electrode UE1 and electrically connected to the second dummy line DML2.

In embodiments, a first dummy pixel and a second dummy pixel arranged in the same row may be electrically connected to different repair lines RPL. For example, in the first row R1, the 11th dummy pixel DP11 may be electrically connected to the second repair line RPL2 and the 12th dummy pixel DP12 may be electrically connected to the first repair line RPL1. In the second row R2, the 21st dummy pixel DP21 may be electrically connected to the first repair line RPL1 and the 22nd dummy pixel DP22 may be electrically connected to the second repair line RPL2.

The 11th dummy pixel circuit DPC11 may be electrically connected to the second repair line RPL2 through the fourth conductive pattern CP4 electrically connected to the second bridge pattern BRP2. The 11th repair modulation circuit RM11 may be electrically connected to the second repair line RPL2 through the first additional conductive pattern ACP1. The 12th dummy pixel circuit DPC12 may be electrically connected to the first repair line RPL1 through the fourth conductive pattern CP4. The 12th repair modulation circuit RM12 may be electrically connected to the first repair line RPL1 through the sixth conductive pattern CP6.

The 21st dummy pixel circuit DPC21 may be electrically connected to the first repair line RPL1 through the fourth conductive pattern CP4 electrically connected to the first bridge pattern BRP1. The 21st repair modulation circuit RM21 may be electrically connected to the first repair line RPL1 through a second additional conductive pattern ACP2. The second dummy pixel circuit DPC22 may be electrically connected to the second repair line RPL2 through the fourth conductive pattern CP4. The 22nd repair modulation circuit RM22 may be electrically connected to the second repair line RPL2 through the sixth conductive pattern CP6.

The second additional conductive pattern ACP2 may include a fifth conductive layer arranged on the sixth insulating layer INS6. One end of the second additional conductive pattern ACP2 may be electrically connected to the sixth conductive pattern CP6 of the 21st dummy pixel DP21 through the contact hole CH through the sixth insulating layer INS6. The other end of the second additional conductive pattern ACP2 may be electrically connected to the first repair line RPL1 through the contact hole CH through the sixth insulating layer INS6 and the fifth insulating layer INS5.

The dummy pixel DP of the first row R1 and the dummy pixel DP of the second row R2 located in the same column may be electrically connected to different bridge patterns (or repair lines). For example, the fourth conductive pattern CP4 of the 11th dummy pixel DP1) of the first row R1 may be electrically connected to the second bridge pattern BRP2 (or the second repair line PL2) through corresponding contact hole CH, and the fourth conductive pattern CP4 of the 21st dummy pixel DP21 of the second row R2 may be electrically connected to the first bridge pattern BRP1 (or the first repair line RPL1) through the corresponding contact hole CH. Further, the fourth conductive pattern CP4 of the 12th dummy pixel DP12 of the first row R1 may be electrically connected to the first repair line RPL1 (or the first bridge pattern BRP1) through the corresponding contact hole CH, and the fourth conductive pattern CP4 of the 22nd dummy pixel DP22 of the second row R2 may be electrically connected to the second repair line RPL2 (or the second bridge pattern BRP2) through the corresponding contact hole CH.

In the first row R1, the first capacitor C1 of the 11th dummy pixel DP11 and the first capacitor C1 of the 12th dummy pixel DP12 may be spaced apart from each other. For example, the first dummy pixel circuit DPC11 of the 11th dummy pixel DP11 may be arranged between the first capacitor C1 of the 11th dummy pixel DP11 and the first capacitor C1 of the 12th dummy pixel DP12. In the second row R2, the first capacitor C1 of the 21st dummy pixel DP21 and the first capacitor C1 of the 22nd dummy pixel DP22 may be spaced apart from each other. For example, the first dummy pixel circuit DPC21 of the first dummy pixel DP21 may be arranged between the first capacitor C1 of the first dummy pixel DP21 and the first capacitor C1 of the second dummy pixel DP22. Hereinafter, for convenience of explanation, the first capacitor C1 of the 11th dummy pixel DP11 is referred to as a (1-1)th capacitor, the first capacitor C1 of the 12th dummy pixel DP12 is referred to as a (1-2)th capacitor, the first capacitor C1 of the 21st dummy pixel DP21 is referred to as a (1-3)th capacitor, and the first capacitor C1 of the 22nd dummy pixel DP22 is referred to as the (1-4)th capacitor.

In embodiments, the size of the (1-1)th capacitor C1 may be greater than the (1-2)th capacitor C1, and the size of the (1-3)th capacitor C1 may be greater than the (1-4)th capacitor C1.

The (1-1)th capacitor C1 and the (1-3)th capacitor C1 may have the same size as each other, and the (1-2)th capacitor C1 and the (1-4)th capacitor C1 may have the same size as each other. However, the present disclosure is not limited thereto. According to embodiments, the size of the (1-1)th capacitor C1 may be greater than the (1-3)th capacitor C1 or vice versa, and the size of the (1-2)th capacitor C1 may be greater than the (1-4)th capacitor C1 or vice versa.

In each of the first and second rows R1 and R2, the first capacitor C1 of the first dummy pixel located far from the first area DA1 (or the sub-pixels) may have a greater size than the first capacitor C1 of the second dummy pixel located adjacent to the first area DA1 (or the sub-pixels). Since the second dummy pixel is located closer to the first area DA1 (or the sub-pixels) than the first dummy pixel, the load of the repair line RPL electrically connecting the sub-pixel with a dark spot failure in the first area DA1 (hereinafter, referred to as the “defective sub-pixel”) and the second dummy pixel may be smaller than the load of the repair line RPL electrically connecting the defective sub-pixel and the first dummy pixel. Therefore, in the above-described embodiment, the first capacitor C1 of the first dummy pixel may be designed to have a greater size than the first capacitor C1 of the second dummy pixel to compensate for the difference between the load of the repair line RPL connected to the first dummy pixel and the load of the repair line RPL connected to the second dummy pixel.

In the first row R1, the (1-1)th capacitor C1 of the first dummy pixel DP11 located farther from the first area DA1 than the 12th dummy pixel DP12 may have a greater size than the (1-1)th capacitor C1 of the second dummy pixel DP12. The overlap area of the second lower electrode LE2 and the second upper electrode UE2 constituting the (1-1)th capacitor C1 may be greater than the overlap area of the second lower electrode LE2 and the second upper electrode UE2 constituting the (1-1)th capacitor C1. Accordingly, the capacitance of the (1-1)th capacitor C1 may be greater than the capacitance of the (1-2)th capacitor C1.

In the second row R2, the (1-3)th capacitor C1 of the 21st dummy pixel DP21 located farther from the first area DA1 than the 22nd dummy pixel DP22 may have a greater size than the (1-4)th capacitor C1 of the 22nd dummy pixel DP22. The overlap area of the second lower electrode LE2 and the second upper electrode UE2 constituting the (1-3)th capacitor C1 may be greater than the overlap area of the second lower electrode LE2 and the second upper electrode UE2 constituting the (1-4)th capacitor C1. Accordingly, the capacitance of the (1-3)th capacitor C1 may be greater than the capacitance of the (1-4)th capacitor C1.

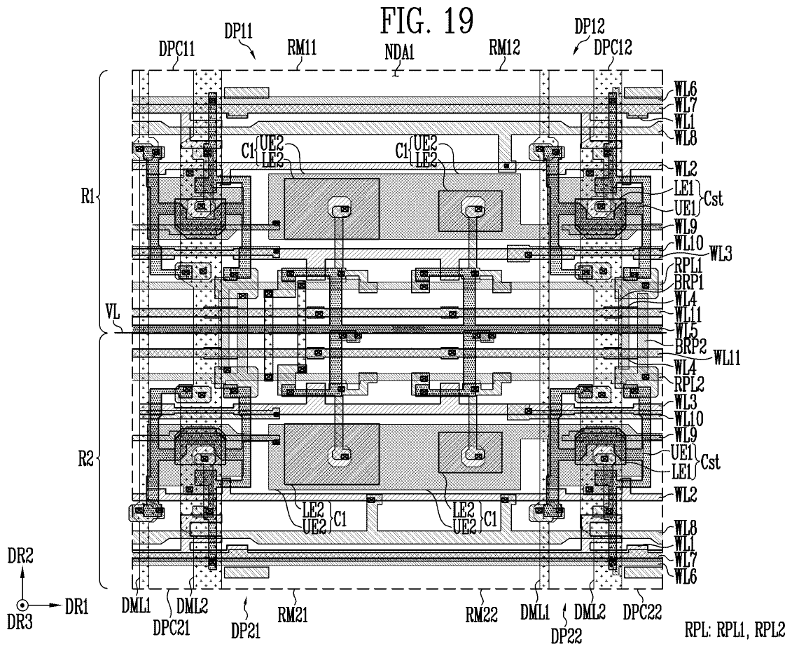

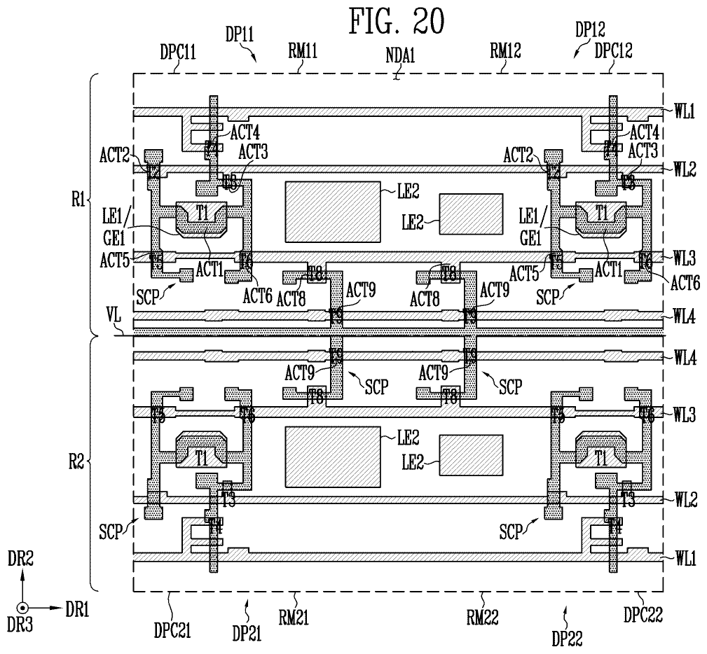

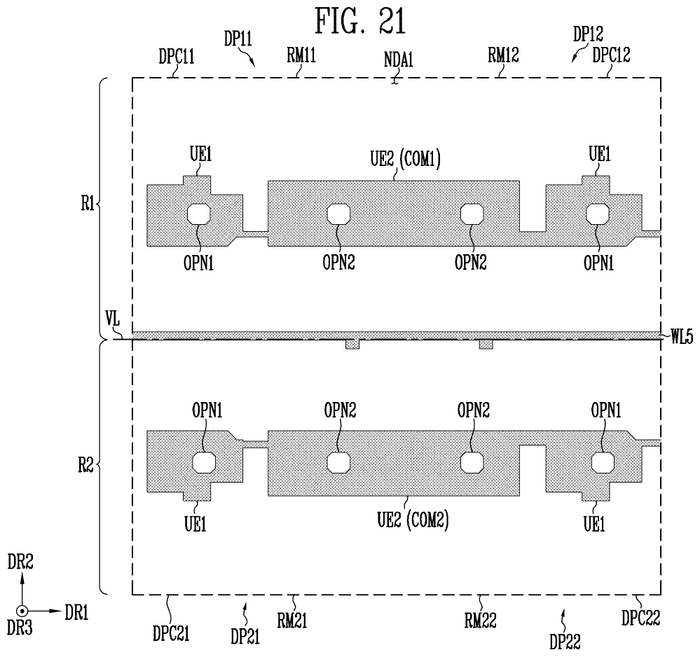

FIG. 19 is a schematic plan view illustrating dummy pixels arranged in the first row R1 and the second row R2 located in a portion of the first non-display area of the display device according to one embodiment. FIG. 20 is a schematic plan view illustrating only the configurations included in the first to sixth transistors T1 to T6, the eighth and ninth transistors T8 and T9, and the first conductive layer in FIG. 19. FIG. 21 is a schematic plan view illustrating only the configurations included in the second conductive layer in FIG. 19.

Differences from the above-described embodiments described will be mainly described with reference to FIGS. 19 to 21 so as to avoid redundant descriptions.

Referring to FIG. 2, and FIGS. 19 to 21, dummy pixels (see “DP” in FIG. 2 may be arranged in each of the first and second rows R1 and R2 of the first non-display area NDA1. For example, the 11th dummy pixel DP11 (or the first dummy pixel) and the 12th dummy pixel DP12 (or the second dummy pixel) arranged in the first direction DR1 may be arranged in the first row R1 (or the first pixel row). The 21st dummy pixel DP21 (or the first dummy pixel) and the 22nd dummy pixel DP22 (or the second dummy pixel) arranged in the first direction DR1 may be arranged in the second row R2 (or the second pixel row).

In an embodiment, the first capacitor C1 of the 11th dummy pixel DP11 and the first capacitor C1 of the 12th dummy pixel DP12 may be arranged adjacent to each other, and the first capacitor C1 of the 21st dummy pixel DP21 and the first capacitor C1 of the 22nd dummy pixel DP22 may be arranged adjacent to each other.

The first capacitor of the 11th dummy pixel DP11 (hereinafter, referred to as the “(1-1)th capacitor”) may include the second lower electrode LE2 and the second upper electrode UE2. The first capacitor (hereinafter, referred to as the “(1-2)th capacitor”) of the 12th dummy pixel DP12 may include the second lower electrode LE2 and the second upper electrode UE2. The second lower electrode LE2 of the (1-1)th capacitor C1 and the second lower electrode LE2 of the (1-1)th capacitor C1 may include a first conductive layer and may be spaced apart from each other. When viewed in a plane, the size of the second lower electrode LE2 of the (1-1)th capacitor C1 may be greater than that of the second lower electrode LE2 of the (1-2)th capacitor C1.

In an embodiment, the second upper electrode UE2 of the (1-1)th capacitor C1 and the second upper electrode UE2 of the (1-2)th capacitor C1 may be integrally formed and connected to each other. The second upper electrode UE2 of the (1-1)th capacitor C1 and the second upper electrode UE2 of the (1-2)th capacitor C1 may be a first common electrode COM1 provided in common to the 11th sub-pixel SP11 and the 12th sub-pixel SP12. The first common electrode COM1 may be large enough to cover the second lower electrode LE2 of the (1-1)th capacitor C1 and the second lower electrode LE2 of the (1-1)th capacitor C1. The first common electrode COM1 may include a second conductive layer and overlap the second lower electrode LE2 of the (1-1)th capacitor C1 and the second lower electrode LE2 of the (1-2)th capacitor C1 with the third insulating layer (see “INS3” in FIG. 6) interposed therebetween. The overlap area of the second lower electrode LE2 of the (1-1)th capacitor C1 and the first common electrode COM1 may be greater than the overlap area of the second lower electrode LE2 of the (1-1)th capacitor C1 and the first common electrode COM1. Accordingly, the capacitance of the (1-1)th capacitor C1 may be greater than the capacitance of the (1-2)th capacitor C1. In other words, the capacitance of the first capacitor C1 of the 11th sub-pixel DP11 may be greater than the capacitance of the first capacitor C1 of the 12th sub-pixel DP12.

The first capacitor (hereinafter, referred to as the “(1-3)th capacitor”) of the 21st dummy pixel DP21 may include the second lower electrode LE2 and the second upper electrode UE2. The first capacitor (hereinafter, referred to as the “(1-4)th capacitor”) of the 22nd dummy pixel DP22 may include the second lower electrode LE2 and the second upper electrode UE2. The second lower electrode LE2 of the (1-3)th capacitor C1 and the second lower electrode LE2 of the (1-4)th capacitor C1 may include the first conductive layer and be spaced apart from each other. When viewed in plan, the size of the second lower electrode LE2 of the (1-3)th capacitor C1 may be greater than that of the second lower electrode LE2 of the (1-4)th capacitor C1.

In an embodiment, the second upper electrode UE2 of the (1-3)th capacitor C1 and the second upper electrode UE2 of the (1-4)th capacitor C1 may be integrally formed and connected to each other. The second upper electrode UE2 of the (1-3)th capacitor C1 and the second upper electrode UE2 of the (1-4)th capacitor C1 may be a second common electrode COM2 provided in common to the 21st sub-pixel SP21 and the 22nd sub-pixel SP22. The second common electrode COM2 may be large enough to cover the second lower electrode LE2 of the (1-3)th capacitor C1 and the second lower electrode LE2 of the (1-4)th capacitor C1. The second common electrode COM2 may include the second conductive layer and overlap the second lower electrode LE2 of the (1-3)th capacitor C1 and the second lower electrode LE2 of the (1-4)th capacitor C1 with the third insulating layer INS3 interposed therebetween. The overlap area of the second lower electrode LE2 of the (1-3)th capacitor C1 and the second common electrode COM2 may be greater than the overlap area of the second lower electrode LE2 of the (1-4)th capacitor C1 and the second common electrode COM2. Accordingly, the capacitance of the (1-3)th capacitor C1 may be greater than the capacitance of the (1-4)th capacitor C1. For example, the capacitance of the first capacitor C1 of the 21st sub-pixel DP21 may be greater than the capacitance of the first capacitor C1 of the 22nd sub-pixel DP22.

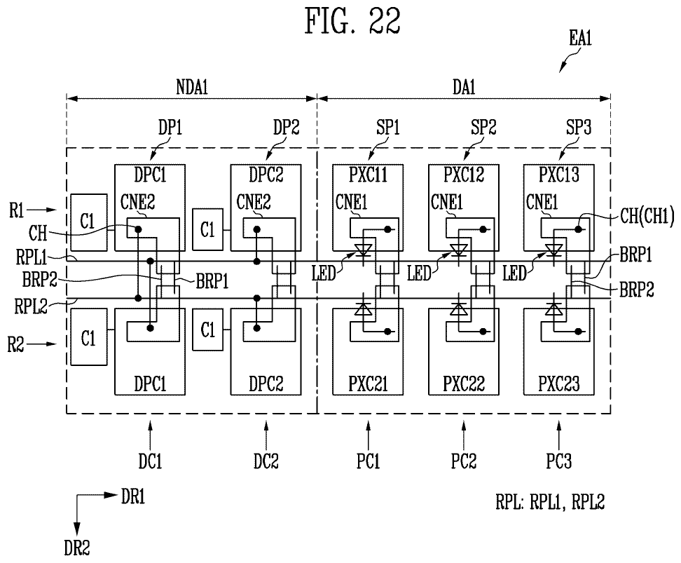

FIG. 22 is a schematic view of the portion EA1 of FIG. 2 for illustrating the sub-pixels in the first area DA1 and the dummy pixels in the first non-display area NDA1 in the display device according to one embodiment.

In FIG. 22, only the first repair line RPL1 and the second repair line RPL2 arranged between the first row R1 and the second row R2 of the signal wiring lines in each of the first display area DA1 and the first non-display area NDA1 are shown for convenience of description.

Referring to FIG. 22, differences from the above-described embodiments are mainly described so as to avoid overlapping descriptions.

Referring to FIGS. 2 and 22, in the first area DA1 (or the first display area), each of the first and second rows R1 and R2 may include the first sub-pixel SP1, the second sub-pixel SP2, and the third sub-pixel SP3 arranged in the first direction DR1. The first sub-pixel SP1 may be arranged in a first pixel column PC1, the second sub-pixel SP2 may be arranged in a second pixel column PC2, and the third sub-pixel SP3 may be arranged in a third pixel column PC3. Each of the first to third sub-pixels SP1 to SP3 may include the pixel circuit “see “PXC” in FIG. 3) and the light-emitting element LED electrically connected to the pixel circuit PXC. The first sub-pixel SP1 of the first row R1 may include the 11th pixel circuit PXC11 and the light-emitting element LED, the second sub-pixel SP2 of the first row R1 may include the 12th pixel circuit PXC12 and the light-emitting element LED, and the third sub-pixel SP3 of the first row R1 may include the 13th pixel circuit PXC13 and the light-emitting element LED. The first sub-pixel SP1 of the second row R2 may include the 21st pixel circuit PXC21 and the light-emitting element LED, the second sub-pixel SP2 of the second row R2 may include the 22nd pixel circuit PXC22 and the light-emitting element LED, and the third sub-pixel SP3 of the second row R2 may include the 23rd pixel circuit PXC23 and the light-emitting element LED.

The pixel circuit PXC of each of the first to third sub-pixels SP1 to SP3 may include the first contact electrode CNE1. The first contact electrode CNE1 may be electrically connected to the light-emitting element LED. The first contact electrode CNE1 may be the fourth conductive pattern CP4 as described above reference to FIGS. 7 to 12.

The first contact electrode CNE1 may electrically connect the light-emitting element LED and some configurations of the pixel circuit PXC. For example, the first contact electrode CNE1 may electrically connect the light-emitting element LED and the sixth transistor (see “T6” in FIG. 3) of the pixel circuit PXC through the corresponding contact hole CH. The first contact electrode CNE1 may be located at a connection point (or the “fourth node N4” in FIG. 3) which electrically connects the light-emitting element LED and the pixel circuit PXC in each sub-pixel. Hereinafter, for convenience of description, the contact hole CH (or connection means) electrically connecting the light-emitting element LED, the first contact electrode CNE1, and the sixth transistor T6 of the pixel circuit PXC will be referred to as the first contact hole CH1.

In the first non-display area NDA1, each of the first and second rows R1 and R2 may include the first dummy pixel DP1 and the second dummy pixel DP2. The first dummy pixel DP1 may be arranged in a first dummy column DC1, and the second dummy pixel DP2 may be arranged in a second dummy column DC2. Each of the first and second dummy pixels DP1 and DP2 may include a dummy pixel circuit and the first capacitor C1 electrically connected to each other. For example, the first dummy pixel DP1 may include the first dummy pixel circuit DPC1 and the first capacitor C1, and the second dummy pixel DP2 may include the second dummy pixel circuit DPC2 and the first capacitor C1. The first capacitor C1 of the first dummy pixel DP1 may have a greater size than the first capacitor C1 of the second dummy pixel DP2.

Each of the first and second dummy pixel circuits DPC1 and DPC2 may include the second contact electrode CNE2 electrically connected to the repair line RPL. The second contact electrode CNE2 may be the fourth conductive pattern CP4 as described with reference to FIGS. 13 to 18. The second contact electrode CNE2 may be electrically connected to the repair line RPL through the corresponding contact hole CH. The contact hole CH may be located at a connection point electrically connecting the repair line RPL and the second contact electrode CNE2 at each dummy pixel.

In an embodiment, the size of the first capacitor C1 of the first dummy pixel DP1 may be greater than that of the second capacitor C2 of the second dummy pixel DP2. To compensate for the difference in the load of the repair line RPL depending on the positions of the first dummy pixel DP1 and the second dummy pixel DP2, the first capacitor C1 of the first dummy pixel DP1 may be designed to have a greater size than the first capacitor C1 of the second dummy pixel DP2.

In each of the first non-display area NDA1 and the first area DA1, the first repair line RPL1 and the second repair line RPL2 may be arranged between the first row R1 and the second row R2. The first repair line RPL1 may be formed integrally with the first bridge pattern BRP1, and the second repair line RPL2 may be formed integrally with the second bridge pattern BRP2.

In the first area DA1, the first bridge pattern BRP1 and the second bridge pattern BRP2 may extend in the second direction DR2 between the sub-pixels in the first row R1 and the sub-pixels in the second row R2. For example, the first bridge pattern BRP1 and the second bridge pattern BRP2 may extend in the second direction DR2 between the first sub-pixel SP1 in the first row R1 and the first sub-pixel SP1 in the second row R2, between the second sub-pixel SP2 in the first row R1 and the second sub-pixel SP2 in the second row R2, and between the third sub-pixel SP3 in the first row R1 and the third sub-pixel SP3 in the second row R2.

In the first area DA1, the first and second bridge patterns BRP1 and BRP2 may overlap the first contact electrode CNE1 of each sub-pixel. Each of the first and second bridge patterns BRP1 and BRP2 may be electrically isolated from the first contact electrode CNE1.

The first repair line RPL1 may be electrically connected to a dummy pixel circuit of one of the first and second dummy pixels DP1 and DP2, and the second repair line RPL2 may be electrically connected to a dummy pixel circuit of the remaining dummy pixels among the first and second dummy pixels DP1 and DP2. For example, each of the second dummy pixel DP2 (or the second dummy pixel circuit DPC2) of the first row R1 and the first dummy pixel DP1 (or the first dummy pixel circuit DPC1) of the second row R2 is electrically connected to the first repair line RPL1 through the corresponding second contact electrode CNE2. Each of the first dummy pixel DP1 (or the first dummy pixel circuit DPC1) of the first row R1 and the second dummy pixel DP2 (or the second dummy pixel circuit DPC2) of the second row R2 may be electrically connected to the second repair line RPL2 through the corresponding second contact electrode CNE2.

The first and second repair lines RPL1 and RPL2 may be electrically isolated from the pixel circuit of each of the first to third sub-pixels SP1 to SP3 located in the first area DA1.

Generally, the display device (see “DD” in FIG. 2) may perform a lighting check on the light-emitting element LED of the sub-pixel (see “SP” in FIG. 2) arranged in the display area (see “DA” in FIG. 2). When the lighting check indicates that some of the light-emitting elements LED are not lit and the sub-pixel SP is darkened, a repair process may be performed by electrically connecting the non-lit light-emitting elements LED to the first and second dummy pixels DP1 and DP2 to drive the light-emitting element LED.

Hereinafter, the repairing method of the sub-pixel SP which is defective in the first area DA1 will be described below.

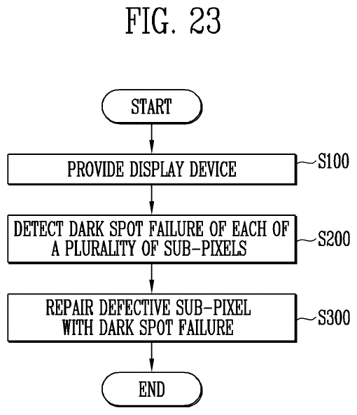

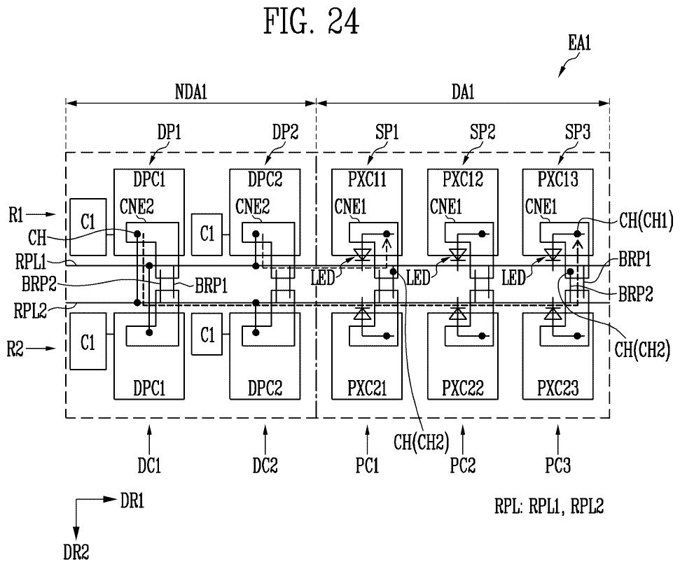

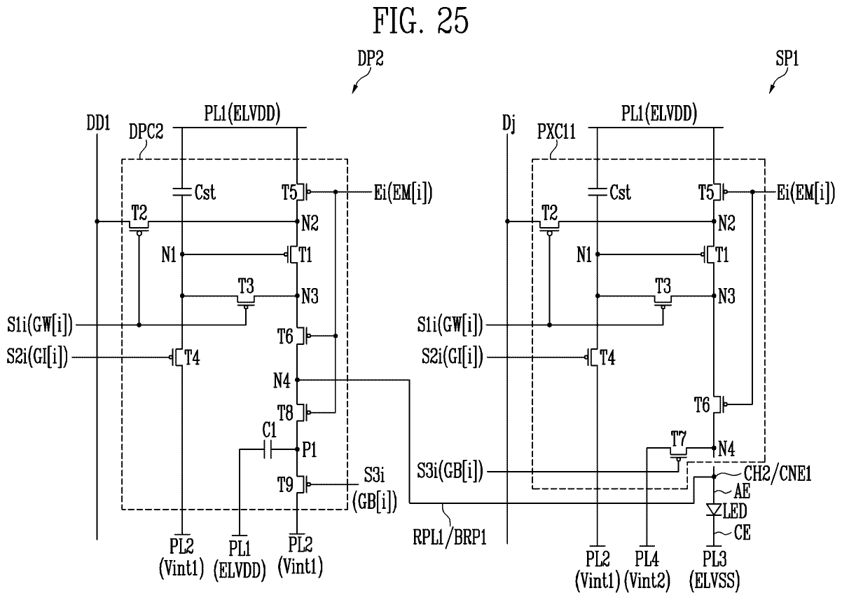

FIG. 23 is a schematic flow diagram illustrating a method of repairing a display device according to one embodiment. FIG. 24 is a schematic view corresponding to the portion EA1 of FIG. 2 for illustrating a method of repairing a defective sub-pixel. FIG. 25 is a schematic circuit diagram illustrating electrical connections of the first sub-pixel SP1 and the second dummy pixel DP2 arranged in the first row of FIG. 24.

Differences from the above-described embodiments will be mainly described with reference to the embodiments of FIGS. 23 to 25 so as to avoid overlapping descriptions.

Referring to FIGS. 23 to 25, the display device (see “DD” in FIG. 2) including the dummy pixel (see “DP” in FIG. 2) and the sub-pixel (see “SP” in FIG. 2) may be provided at step S100.

By the repairing method, dark spot defects of the sub-pixels SP arranged in each of the first area DA1 (or the first display area) and the second area (see “DA2” in FIG. 2) (or the second display area) may be detected at step S200.

When two sub-pixels in the first row R1 of the first area DA1 have dark spot failures, the first dummy pixel (see “DP1” in FIG. 2) and the second dummy pixel (see “DP2” in FIG. 2) arranged in the first row R1 of the first non-display area NDA1 may be electrically connected to the two sub-pixels to repair the dark spot failures of the two sub-pixels at step S300.

The repair process may include, for example, using a laser to disconnect the electrical connection of the light-emitting element from the pixel circuit and the pixel circuit in the sub-pixel with the dark spot failure, and performing a bonding process using a laser to electrically connect the light-emitting element to the dummy pixel DP arranged in the same row as the sub-pixel with the dark spot failure through the repair line (“RPL”), so that the light-emitting element may operating normally.

As shown in FIG. 24, when dark spot failures occur simultaneously in the first sub-pixel SP1 and the third sub-pixel SP3 arranged in the first row R1, a repair process may be performed in which the first sub-pixel SP1 is electrically connected to the second dummy pixel DP2 arranged in the first row R1, and the third sub-pixel SP3 is electrically connected to the first dummy pixel DP1 arranged in the first row R1. The dark spot failure of each of the first and third sub-pixels SP1 and SP3 may be caused by, for example, a defect in the pixel circuit.

When the 11th pixel circuit PXC11 of the first sub-pixel SP1 is defective, the anode electrode AE of the light-emitting element LED (hereinafter, referred to as a “first light-emitting element”) electrically connected to the 11th pixel circuit PXC11 and the sixth and seventh transistors T6 and T7 of the 11th pixel circuit PXC11 may be disconnected from each other using a laser. As a result, the anode electrode AE and the sixth and seventh transistors T6 and T7 may be electrically disconnected from each other. The contact hole CH (or a second contact hole CH2) may be formed between the first contact electrode CNE1 and the first bridge pattern BRP1 electrically connected to the anode electrode AE (or the first light-emitting element LED) through the first contact hole CH1 by destroying the insulating layer using a laser bonding process.

Through the contact hole CH (or the second contact hole CH2), the first contact electrode CNE1, and the first contact hole CH1, the first bridge pattern BRP1 (or the first repair line RPL1) and the anode electrode AE (or the (1-1)th light-emitting element LED) may be electrically connected. The first repair line RPL1 is electrically connected to the second dummy pixel DP2 arranged in the first row R1 of the first non-display area NDA1, so that the second dummy pixel circuit DPC2 of the second dummy pixel DP2 and the (1-1)th light-emitting element LED of the first sub-pixel SP1 may be electrically connected. Accordingly, an electrical path is formed from the second dummy pixel DP2 to the first light-emitting element LED of the first sub-pixel SP1 through the first repair line RPL1 such that the first light-emitting element LED may operate normally and the first sub-pixel SP1 having a dark spot defect may be repaired.

When a dark spot failure occurs in the third sub-pixel SP3 arranged in the same row as the first sub-pixel SP1, the light-emitting element LED (hereinafter, a “second light-emitting element”) electrically connected to the 13th pixel circuit PXC13 of the third sub-pixel SP3 may be disconnected from the anode electrode AE and the sixth and seventh transistors T6 and T7 of the 13th pixel circuit PXC13. As a result, the anode electrode AE of the third light-emitting element LED and the sixth and seventh transistors T6 and T7 may be electrically disconnected from each other. The contact hole CH (or the second contact hole CH2) may be formed by destroying the insulating layer using a laser bonding process between the first contact electrode CNE1 and the second bridge pattern BRP2 electrically connected to the anode electrode AE of the second light-emitting element LED through the first contact hole CH1.

Through the contact hole CH (or the second contact hole CH2), the first contact electrode CNE1, and the first contact hole CH1, the second bridge pattern BRP2 (or the second repair line RPL2), and anode electrode AE of the second light-emitting element LED may be electrically connected. The second repair line RPL2 is electrically connected to the first dummy pixel DP1 arranged in the first row R1 of the first non-display area NDA1, so that the first dummy pixel circuit DPC1 of the first dummy pixel DP1 and the (3-1)th light-emitting element LED of the third sub-pixel SP3 may be electrically connected. Accordingly, an electrical path is formed from the first dummy pixel DP1 to the second light-emitting element LED of the third sub-pixel SP3 through the second repair line RPL2 such that the second light-emitting element LED may operate normally, and the third sub-pixel SP3 having a dark spot defect may be repaired.

As described above, when a dark spot failure occurs in the two sub-pixels arranged in the first row R1 of the first area DA1, the light-emitting element LED of one of the two sub-pixels for one horizontal time is electrically connected to the dummy pixel circuit of one of the first and second dummy pixels DP1 and DP2 arranged in the first row R1 of the first non-display area NDA1, and the light-emitting element LED of the other two sub-pixels may be electrically connected to the dummy pixel circuit of one of the first and second dummy pixels DP1 and DP2. Accordingly, the dark spot defects of the two sub-pixels in one row (or one pixel row) in the first area DA1 may be repaired.

In addition, as described above, the first capacitor C1 of the first dummy pixel DP1 located away from the first area DA1 (or the sub-pixels) may be designed to be greater than the first capacitor C1 of the second dummy pixel DP2 to reduce the load difference of the repair line RPL according to the positions of the first dummy pixel DP1 and the second dummy pixel DP2.

In the embodiment described above, the first area DA1 is described mainly for convenience of description, but the present disclosure is not limited thereto, and any sub-pixels with dark spot defects may also be repaired in the second area (see “DA2” in FIG. 2). For example, when two sub-pixels in the first row in the second area DA2 (or the second display area) have dark spot failures, the light-emitting element LED of one of the two sub-pixels is electrically connected to the dummy pixel circuit of one of the third and fourth dummy pixels (see “DP3 and DP4” in FIG. 2) arranged in the first row of the second non-display area (see “NDA2” in FIG. 2), and the light-emitting elements LED of the other sub-pixel may be electrically connected to the dummy pixel circuit of the other dummy pixel between the third and fourth dummy pixels DP3 and DP4. Accordingly, the dark spot defects of the two sub-pixels in one row (or one pixel row) in the second area DA2 may be repaired.

According to the embodiment described above, by simultaneously repairing the dark spot defects of two sub-pixels in one row (or one pixel row) of each of the first area DA1 (or the first display area) and the second area DA2 (or the second display area), the number of repairable sub-pixels for one horizontal time may be increased, thereby improving the product yield.

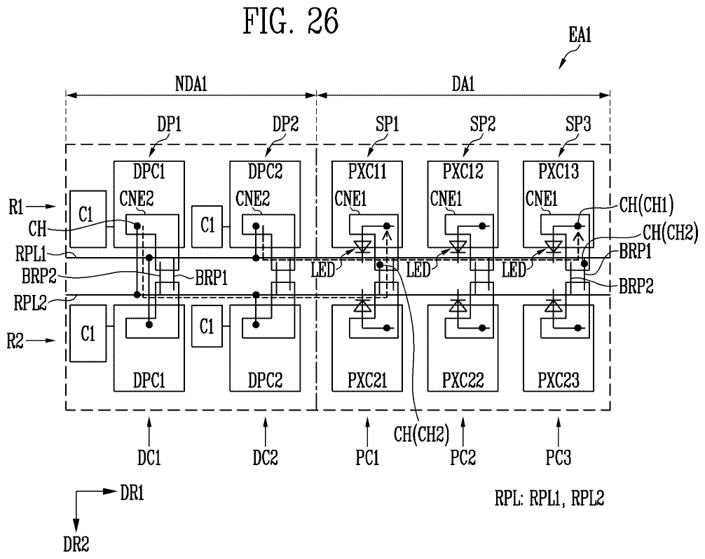

FIG. 26 is a schematic view corresponding to the portion EA1 of FIG. 2 for illustrating a method of repairing a bad sub-pixel. In particular, FIG. 26 illustrates a modification example of FIG. 26 with respect to an electrical path of a dummy pixel and the bad sub-pixel.

With respect to the embodiment of FIG. 26, to avoid redundant descriptions, the differences from the above-described embodiments will be mainly described.

Referring to FIGS. 2 and 26, in the first row R1, when the 11th pixel circuit PXC11 of the first sub-pixel SP1 and the 13th pixel circuit PXC13 of the third sub-pixel SP3 are defective, the light-emitting element LED of the first sub-pixel SP1 (hereinafter, referred to as a “(1-1)th light-emitting element”) is electrically connected to the first dummy pixel DP1 arranged in the first row R1, and the light-emitting element LED of the third sub-pixel SP3 (hereinafter, referred to as the “(1-1)th light-emitting element”) of the first sub-pixel SP1 is electrically connected to the first dummy pixel DP1 arranged in the first row R1, and the light-emitting element LED of the third sub-pixel SP3 (hereinafter, referred to as the “second light-emitting element”) is electrically connected to the second dummy pixel DP2 arranged in the first row R1. The first dummy pixel circuit DPC1 of the first dummy pixel DP1 may be electrically connected to the second repair line RPL2, and the second dummy pixel circuit DPC2 of the second dummy pixel DP2 may be electrically connected to the first repair line RPL1.

More specifically, an electrical connection between the first light-emitting element LED and some configuration of the 11th pixel circuit PXC11 is released, and the contact hole CH (or the second contact hole CH2) is formed between the first contact electrode CNE1 of the first sub-pixel SP1 and the second bridge pattern BRP2 to electrically connect the (1-1)th light-emitting element LED and the second repair line RPL2 connected to the second bridge pattern BRP2, so that the (1-1)th light-emitting element LED and the first dummy pixel circuit DPC1 of the first dummy pixel DP1 may be electrically connected.

Further, the electrical connection between the second light-emitting element LED and some configurations of the 13th pixel circuit PXC13 is released, and the contact hole CH (or the second contact hole CH2) is formed between the first contact electrode CNE1 and the first bridge pattern BRP1 of the third sub-pixel SP3 to electrically connect the second light-emitting element LED and the first repair line RPL1 connected to the first bridge pattern BRP1, so that the second light-emitting element LED and the second dummy pixel circuit DPC2 of the second dummy pixel DP2 may be electrically connected.

As described above, an electrical path is formed from the first dummy pixel DP1 to the (1-1)th light-emitting element LED of the first sub-pixel SP1 having a dark spot defect through the second repair line RPL2, and an electrical path is formed from the second dummy pixel DP2 to the second light-emitting element LED of the third sub-pixel SP3 having a dark spot defect through the first repair line RPL1. Thus, a signal delay phenomenon due to the difference in the electrical path between the dummy pixel and the sub-pixel in which the dark spot defect occurs may be reduced or prevented. In other words, the signal delay phenomenon due to the difference in length between the first repair line RPL1 and the second repair line RPL2 electrically connecting the dummy pixel and the defective sub-pixel may be reduced or prevented.

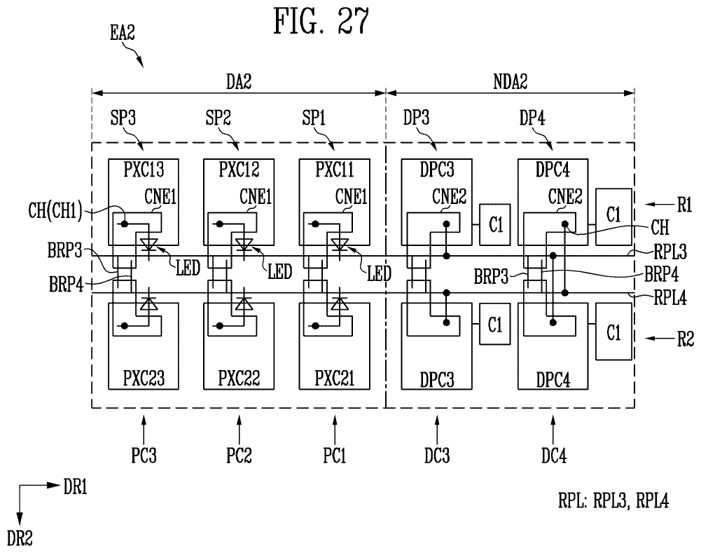

FIG. 27 is a schematic view of the portion EA2 of FIG. 2 for illustrating sub-pixels in a second area and dummy pixels in a second non-display area in a display device according to one embodiment.

Referring to FIG. 27, differences from the above-described embodiments are mainly described so as to avoid overlapping descriptions.

Referring to FIGS. 2 and 27, in the second area DA2 (or the second display area), each of the first and second rows R1 and R2 may include the third sub-pixel SP3, the second sub-pixel SP2, and the first sub-pixel SP1 arranged in the first direction DR1. The first sub-pixel SP1, the second sub-pixel SP2, and the third sub-pixel SP3 may be arranged in order in an opposite direction to the first direction DR1, based on the boundary of the second area DA2 and the second non-display area NDA2. The pixel circuit of each of the first to third sub-pixels SP1 to SP3 may include the first contact electrode CNE1. Each of the first and second sub-pixels SP1 to SP3 may include the pixel circuit (see “PXC” in FIG. 3) and the light-emitting element LED. The pixel circuit PXC of each of the first to third sub-pixels SP1 to SP3 may include the first contact electrode CNE1. The first contact electrode CNE1 may be electrically connected to the light-emitting element LED through the corresponding contact hole CH.

The third dummy pixel DP3 and the fourth dummy pixel DP4 may be arranged in each of the first and second rows R1 and R2 of the second non-display area NDA2. The third dummy pixel DP3 may be arranged in the third dummy column DC3, and the fourth dummy pixel DP4 may be arranged in the fourth dummy column DC4. Each of the third and fourth dummy pixels DP3 and DP4 may include the dummy pixel circuit and the first capacitor C1 electrically connected to each other. For example, the third dummy pixel DP3 may include the third dummy pixel circuit DPC3 and the first capacitor C1, and the fourth dummy pixel DP4 may include the fourth dummy pixel circuit DPC4 and the first capacitor C1. The first capacitor C1 of the fourth dummy pixel DP4 may have a greater size than the first capacitor C1 of the third dummy pixel DP3.

Each of the third and fourth dummy pixel circuits DPC3 and DPC4 may include the second contact electrode CNE2 electrically connected to the repair line RPL. The second contact electrode CNE2 may be electrically connected to the repair line RPL through the corresponding contact hole CH.

In an embodiment, the first capacitor C1 of the fourth dummy pixel DP4 may have a greater size than the first capacitor C1 of the third dummy pixel DP3. In each of the first and second rows R1 and R2, the first capacitor C1 of the fourth dummy pixel DP4 located far from the second region DA2 (or the sub-pixels) may have a greater size than the first capacitor C1 of the third dummy pixel DP3 located adjacent to the second region DA2 (or the sub-pixels). Since the third dummy pixel DP3 is located closer to the second region DA2 than the fourth dummy pixel DP4, the load of the repair line RPL electrically connecting the sub-pixel with the dark spot failure in the second region DA2 and the third dummy pixel DP3 may be smaller than the load of the repair line RPL electrically connecting the sub-pixel with the dark spot failure and the fourth dummy pixel DP4. Therefore, in order to compensate for the difference between the load of the repair line RPL connected to the third dummy pixel DP3 and the load of the repair line RPL connected to the fourth dummy pixel DP4, the first capacitor C1 of the fourth dummy pixel DP4 may be designed to have a greater size than the first capacitor C1 of the third dummy pixel DP3.

In each of the second non-display area NDA2 and the second area DA2, the third repair line RPL3 and the fourth repair line RPL4 may be arranged between the first row R1 and the second row R2. The third repair line RPL3 may be formed integrally with the third bridge pattern BRP3, and the fourth repair line RPL4 may be formed integrally with the fourth bridge pattern BRP4.

In the second area DA2, the third bridge pattern BRP3 and the fourth bridge pattern BRP4 may extend in the second direction DR2 between the sub-pixels in the first row R1 and the sub-pixels in the second row R2. For example, the third bridge pattern BRP3 and the fourth bridge pattern BRP4 may extend in the second direction DR2 between the first sub-pixel SP1 in the first row R1 and the first sub-pixel SP1 in the second row R2, between the second sub-pixel SP2 of the first row R1 and the second sub-pixel SP2 of the second row R2, and between the third sub-pixel SP3 of the first row R1 and the third sub-pixel SP3 of the second row R2.

In the second area DA2, the third and fourth bridge patterns BRP3 and BRP4 may overlap the first contact electrode CNE1 of each sub-pixel. Each of the third and fourth bridge patterns BRP3 and BRP4 may be electrically isolated from the first contact electrode CNE1.

The third repair line RPL3 may be electrically connected to one of the third and fourth dummy pixels DP3 and DP4, and the fourth repair line RPL4 may be electrically connected to the other dummy pixel between the third and fourth dummy pixels DP3 and DP4. For example, each of the third dummy pixel DP3 (or the third dummy pixel circuit DPC3) of the first row R1 and the fourth dummy pixel DP4 (or the fourth dummy pixel circuit DPC4) of the second row R2 are electrically connected to the third repair line RPL3 through the corresponding second contact electrode CNE2, and each of the fourth dummy pixel DP4 (or the fourth dummy pixel circuit DPC4) in the first row R1 and the third dummy pixel DP3 (or the third dummy pixel circuit DPC3) in the second row R2 may be electrically connected to the second repair line RPL2 through the corresponding second contact electrode CNE2.

The third and fourth repair lines RPL3 and RPL4 may be electrically isolated from the pixel circuit of each of the first to third sub-pixels SP1 to SP3 located in the second area DA2.

Generally, the display device (see “DD” in FIG. 2) may perform a lighting check on the light-emitting elements LED of the sub-pixels arranged in the display area (see “DA” in FIG. 2). When the lighting check indicates that some of the light-emitting elements LED are not lit, causing the sub-pixels to be dark, a repair process may be performed by electrically connecting the non-lit light-emitting element LED to the third and fourth dummy pixels DP3 and DP4 to drive the light-emitting element LED.

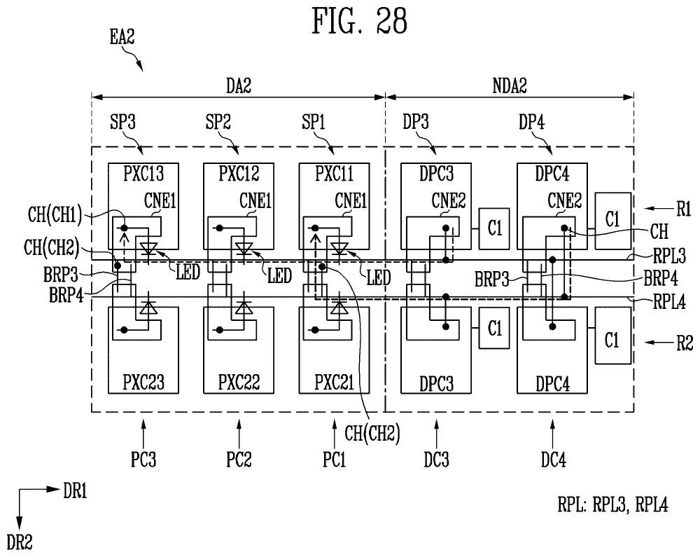

Hereinafter, referring to FIG. 28, a method of repairing a defective sub-pixel in the second area DA2 will be described.

FIG. 28 is a schematic view for illustrating a method of repairing a bad sub-pixel corresponding to a portion EA2 of FIG. 2.

With respect to the embodiment of FIG. 28, to avoid redundant description, the differences from the above-described embodiments will be emphasized.

Referring to FIGS. 2 and 28, when a dark spot failure occurs simultaneously in the first sub-pixel SP1 and the third sub-pixel SP3 arranged in the first row R1, a repair process may be performed in which the first sub-pixel SP1 is electrically connected to the fourth dummy pixel DP4 arranged in the first row R1, and the third sub-pixel SP3 is electrically connected to the third dummy pixel DP3 arranged in the first row R1. The dark spot defect of each of the first and third sub-pixels SP1 and SP3 may be caused by, for example, a defect in the pixel circuit.

When the 11th pixel circuit PXC11 of the first sub-pixel SP1 is defective, the electrical connection between the anode electrode (see “AE” in FIG. 3) of the light-emitting element LED (hereinafter, referred to as the “first light-emitting element”) electrically connected to the 11th pixel circuit PXC11 and the sixth and seventh transistors (see “T6 and T7” in FIG. 3) of the 11th pixel circuit PXC11 may be electrically disconnected from each other using a laser. As a result, the anode electrode AE and the may be electrically disconnected from each other. The contact hole CH (or a second contact hole CH2) may be formed between the first contact electrode CNE1 and the fourth bridge pattern BRP4 electrically connected to the anode electrode AE (or the first light-emitting element LED) through the first contact hole CH1 by destroying the insulating layer using a laser bonding process.

Through the contact hole CH (or the second contact hole CH2), the first contact electrode CNE1, and the first contact hole CH1, the fourth bridge pattern BRP4 (or the fourth repair line RPL4) and the anode electrode AE (or the first light-emitting element LED) may be electrically connected to each other. The fourth repair line RPL4 is electrically connected to the fourth dummy pixel DP4 arranged in the first row R1 of the second non-display area NDA2, so that the fourth dummy pixel circuit DPC4 of the fourth dummy pixel DP4 and the first light-emitting element LED of the first sub-pixel SP1 may be electrically connected to each other. Accordingly, an electrical path is formed from the fourth dummy pixel DP4 to the first light-emitting element LED of the first sub-pixel SP1 through the fourth repair line RPL4, so that the first light-emitting element LED may operate normally and the first sub-pixel SP1 having a dark spot defect may be repaired.

When a dark spot failure also occurs in the third sub-pixel SP3 arranged in the same row as the first sub-pixel SP1, the electrical connection between the anode electrode AE of the light-emitting element LED (hereinafter, referred to as the “second light-emitting element”) electrically connected to the 13th pixel circuit PXC13 of the third sub-pixel SP3 and the sixth and seventh transistors T6 and T7 of the 13th pixel circuit PXC13 may be released. As a result, the anode electrode AE of the second light-emitting element LED and the sixth and seventh transistors T6 and T7 may be electrically disconnected from each other. The contact hole CH (or the second contact hole CH2) may be formed by destroying the insulating layer using a laser bonding process between the first contact electrode CNE1 and the third bridge pattern BRP3 electrically connected to the anode electrode AE of the second light-emitting element LED through the first contact hole CH1.

Through the contact hole CH (or the second contact hole CH2), the first contact electrode CNE1, and the first contact hole CH1, the third bridge pattern BRP3 (or the third repair line RPL3) and the anode electrode AE of the second light-emitting element LED may be electrically connected to each other. The third repair line RPL3 is electrically connected to the third dummy pixel DP3 arranged in the first row R1 of the second non-display area NDA2, so that the third dummy pixel circuit DPC3 of the third dummy pixel DP3 and the second light-emitting element LED of the third sub-pixel SP3 may be electrically connected to each other. Accordingly, an electrical path is formed from the third dummy pixel DP3 to the second light-emitting element LED of the third sub-pixel SP3 through the third repair line RPL3, so that the second light-emitting element LED may operate normally and the third sub-pixel SP3 having a dark spot defect may be repaired.

As described above, when a dark spot failure occurs in the two sub-pixels arranged in the first row R1 of the first area DA1, the light-emitting element LED of one of the two sub-pixels for one horizontal time is electrically connected to the dummy pixel circuit of one of the first and second dummy pixels DP1 and DP2 arranged in the first row R1 of the first non-display area NDA1, and the light-emitting element LED of the other two sub-pixels may be electrically connected to the dummy pixel circuit of one of the first and second dummy pixels DP1 and DP2. Accordingly, the dark spot defects of the two sub-pixels in one row (or one pixel row) in the first area DA1 may be repaired.

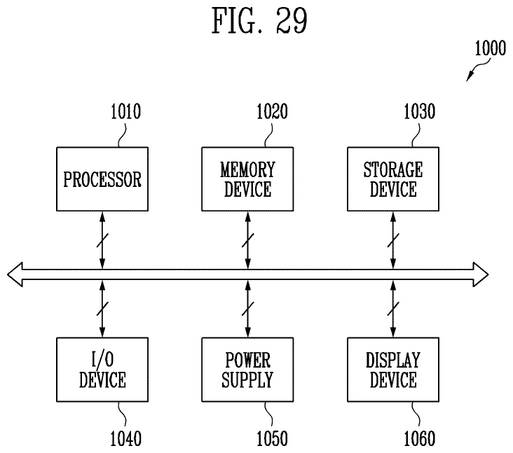

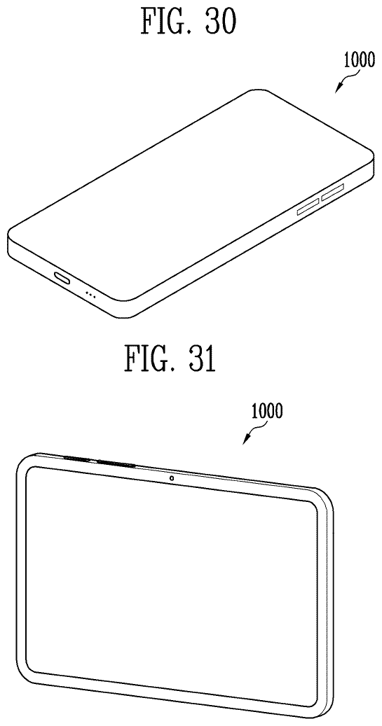

FIG. 29 is a schematic block diagram illustrating an electronic device 1000 according to embodiments. FIG. 30 is a schematic diagram illustrating an example in which the electronic device 1000 of FIG. 29 is a smartphone. FIG. 31 is a schematic view illustrating an example in which the electronic device 1000 of FIG. 29 is a tablet PC.

Referring to FIGS. 29 to 31, the electronic device 1000 may include a processor 1010, a memory device 1020, a storage device 1030, an input/output (I/O) device 1040, a power supply 1050, and a display device 1060. The display device 1060 may be the display device DD of FIGS. 1 and 2. The electronic device 1000 may further include various ports for communication with a video card, a sound card, a memory card, a USB device, or other systems. In an embodiment, as illustrated in FIG. 30, the electronic device 1000 may be a smartphone. In an embodiment, as illustrated in FIG. 31, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus.

The memory device 1020 may store data needed to perform the operation of the electronic device 1000. For example, the memory device 1020 may include non-volatile memory devices such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM), and a Ferroelectric Random Access Memory (FRAM) device, and/or a volatile memory device such as a Dynamic Random Access Memory (DRAM) device, a Static Random Access Memory (SRAM) device, and a mobile DRAM device.

The storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may include a power management integrated circuit (PMIC).

The display device 1060 may display images in response to control signals or data from the processor 1010. The display device 1060 may be an organic light emitting display device or a quantum dot light emitting display device, but the present disclosure is not limited to these. The display device 1060 may be connected to other components through the buses or other communication links.

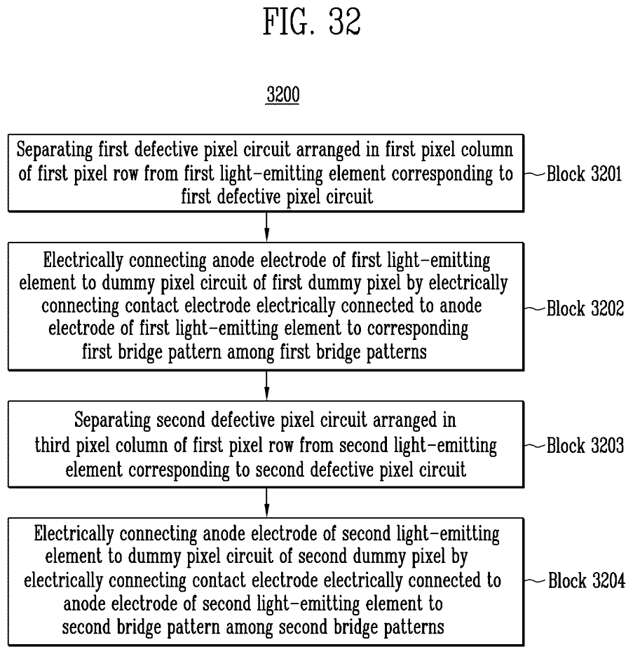

With reference to FIG. 32, a method 3200 of repairing a display device is provided. As generally described above, the display device includes a substrate in which a display area including a first area and a second area and a non-display area surrounding at least one side of the first and second areas are defined, a sub-pixel arranged in the display area and including a pixel circuit, a light-emitting element, and a contact electrode electrically connected to an anode electrode of the light-emitting element, first and second repair lines arranged between a first pixel row and a second pixel row and spaced apart from each other in the display area, a first dummy pixel and a second dummy pixel arranged in the non-display area corresponding to the first pixel row and the second pixel row, respectively, and connected to the first repair line and the second repair line, first bridge patterns electrically connected to the first repair line, and second bridge patterns electrically connected to the second repair line. As shown in FIG. 32, the method 3200 includes separating a first defective pixel circuit arranged in a first pixel column of the first pixel row from a first light-emitting element corresponding to the first defective pixel circuit (block 3201), electrically connecting an anode electrode of the first light-emitting element to a dummy pixel circuit of the first dummy pixel by electrically connecting the contact electrode electrically connected to the anode electrode of the first light-emitting element to a corresponding first bridge pattern among the first bridge patterns (block 3202), separating a second defective pixel circuit arranged in a third pixel column of the first pixel row from a second light-emitting element corresponding to the second defective pixel circuit (block 3203) and electrically connecting an anode electrode of the second light-emitting element to a dummy pixel circuit of the second dummy pixel by electrically connecting the contact electrode electrically connected to the anode electrode of the second light-emitting element to a second bridge pattern among the second bridge patterns (block 3204). In accordance with the method 3200, each of the first and second dummy pixels includes a first capacitor electrically connected to the dummy pixel circuit and the first capacitor of the first dummy pixel and the first capacitor of the second dummy pixel have different sizes. In addition, in accordance with the method 3200, the second dummy pixel is located closer to the display area than the first dummy pixel in the non-display area, and the first capacitor of the first dummy pixel has a greater size than the first capacitor of the second dummy pixel.

A display device and a repairing method thereof according to embodiments may improve the reliability of the display device by easily repairing dark spot failures occurring in four sub-pixels in a pixel row at the same time.

According to embodiments, the yield of a product may be improved by increasing the number of repairable sub-pixels.

Furthermore, according to embodiments, an electronic device including the above-described display device may be provided.

The effects of the present disclosure are not limited by the foregoing, and other various effects are anticipated herein.

What is claimed is:

1. A display device, comprising:
a substrate in which a display area including a first area and a second area and a non-display area surrounding at least one side of the display area are defined;
a sub-pixel arranged in the display area;
first and second dummy pixels arranged in the non-display area; and
a repair line commonly provided to the display area and the non-display area and extending in a first direction,
wherein:
the non-display area includes a first non-display area adjacent to the first area and a second non-display area adjacent to the second area,
the repair line includes a first repair line and a second repair line arranged between a first pixel row and a second pixel row of the substrate in the first area,
each of the first and second dummy pixels includes a dummy pixel circuit and a first capacitor electrically connected to the dummy pixel circuit, and
the first capacitor of the first dummy pixel and the first capacitor of the second dummy pixel have different sizes.

2. The display device of claim 1, wherein:
the second dummy pixel is located closer to the first area than the first dummy pixel in the first non-display area, and
the first capacitor of the first dummy pixel has a greater size than the first capacitor of the second dummy pixel.

3. The display device of claim 2, wherein the first capacitor of each of the first and second dummy pixels includes:
a lower electrode arranged on the substrate; and
an upper electrode arranged on the lower electrode with an insulating layer interposed therebetween, and
wherein an overlap area between the lower electrode and the upper electrode in the first dummy pixel is greater than an overlap area between the lower electrode and the upper electrode in the second dummy pixel.

4. The display device of claim 3, wherein the dummy pixel circuit of the first dummy pixel is arranged between the first capacitor of the first dummy pixel and the first capacitor of the second dummy pixel in a plan view.

5. The display device of claim 3, wherein the first capacitor of the first dummy pixel and the first capacitor of the second dummy pixel are arranged adjacent to each other in a plan view.

6. The display device of claim 5, wherein the upper electrode of the first capacitor of the first dummy pixel and the upper electrode of the first capacitor of the second dummy pixel are common electrodes provided in common to the first dummy pixel and the second dummy pixel.

7. The display device of claim 2, wherein the first repair line and the second repair line extend in the first direction, are spaced apart from each other in a second direction, and are electrically isolated from each other.

8. The display device of claim 7, wherein:
the dummy pixel circuit of the first dummy pixel is electrically connected to one of the first and second repair lines, and
the dummy pixel circuit of the second dummy pixel is electrically connected to the other one of the first and second repair lines.

9. The display device of claim 8, wherein:
the dummy pixel circuit of the first dummy pixel is electrically connected to the second repair line, and
the dummy pixel circuit of the second dummy pixel is electrically connected to the first repair line.

10. The display device of claim 9, further comprising:
a first bridge pattern located between the first repair line and the second repair line, extending in the second direction, and electrically connected to the first repair line; and
a second bridge pattern located between the first repair line and the second repair line, extending in the second direction, and electrically connected to the second repair line.

11. The display device of claim 10, wherein the sub-pixel includes:
a pixel circuit including at least one transistor arranged on the substrate;
a light-emitting element electrically connected to the transistor and emitting light; and
a first contact electrode electrically connecting the light-emitting element and the transistor,
wherein:
the first contact electrode overlaps the first and second bridge patterns, and
the first contact electrode, the first bridge pattern, and the second bridge pattern are electrically isolated from each other.

12. The display device of claim 11, wherein pixel circuits of two sub-pixels facing each other in the second direction while interposing the first and second repair lines in the first area are mirror symmetrical relative to each other.

13. The display device of claim 10, wherein:
each of the first and second dummy pixels further includes a second contact electrode electrically connecting the dummy pixel circuit to a corresponding repair line among the first and second repair lines,
the second contact electrode overlaps the first and second bridge patterns, and
the second contact electrode is electrically connected to one of the first and second bridge patterns.

14. The display device of claim 1, wherein:
the repair line further includes a third repair line and a fourth repair line arranged between the first pixel row and the second pixel row in the second area,
a third dummy pixel and a fourth dummy pixel are arranged in the second non-display area to correspond to the first pixel row and the second pixel row, respectively,
the third dummy pixel is electrically connected to one of the third and fourth repair lines, and
the fourth dummy pixel is electrically connected to the other one of the third and fourth repair lines.

15. The display device of claim 14, wherein:
each of the third and fourth dummy pixels includes the dummy pixel circuit and the first capacitor electrically connected to the dummy pixel circuit, and
the first capacitor of the third dummy pixel and the first capacitor of the fourth dummy pixel have different sizes.

16. The display device of claim 15, wherein:
the third dummy pixel is located closer to the second area than the fourth dummy pixel in the second non-display area, and
the first capacitor of the fourth dummy pixel has a greater size than the first capacitor of the third dummy pixel.

17. A method of repairing a display device including a substrate in which a display area including a first area and a second area and a non-display area surrounding at least one side of the first and second areas are defined, a sub-pixel arranged in the display area and including a pixel circuit, a light-emitting element, and a contact electrode electrically connected to an anode electrode of the light-emitting element, first and second repair lines arranged between a first pixel row and a second pixel row and spaced apart from each other in the display area, a first dummy pixel and a second dummy pixel arranged in the non-display area corresponding to the first pixel row and the second pixel row, respectively, and connected to the first repair line and the second repair line, first bridge patterns electrically connected to the first repair line, and second bridge patterns electrically connected to the second repair line, the method comprising:
separating a first defective pixel circuit arranged in a first pixel column of the first pixel row from a first light-emitting element corresponding to the first defective pixel circuit;
electrically connecting an anode electrode of the first light-emitting element to a dummy pixel circuit of the first dummy pixel by electrically connecting the contact electrode electrically connected to the anode electrode of the first light-emitting element to a corresponding first bridge pattern among the first bridge patterns;
separating a second defective pixel circuit arranged in a third pixel column of the first pixel row from a second light-emitting element corresponding to the second defective pixel circuit; and
electrically connecting an anode electrode of the second light-emitting element to a dummy pixel circuit of the second dummy pixel by electrically connecting the contact electrode electrically connected to the anode electrode of the second light-emitting element to a second bridge pattern among the second bridge patterns,
wherein:
each of the first and second dummy pixels includes a first capacitor electrically connected to the dummy pixel circuit, and
the first capacitor of the first dummy pixel and the first capacitor of the second dummy pixel have different sizes.

18. The method of claim 17, wherein:
the second dummy pixel is located closer to the display area than the first dummy pixel in the non-display area, and
the first capacitor of the first dummy pixel has a greater size than the first capacitor of the second dummy pixel.

19. An electronic device, comprising:
a processor providing input image data to a display device; and
the display device displaying an image based on the input image data,
wherein the display device includes:
a substrate in which a display area including a first area and a second area and a non-display area surrounding at least one side of the display area are defined;
a sub-pixel arranged in the display area;
a dummy pixel arranged in the non-display area; and
a repair line commonly provided to the display area and the non-display area and extending in a first direction,
wherein:
the non-display area includes a first non-display area adjacent to the first area and a second non-display area adjacent to the second area,
the repair line includes a first repair line and a second repair line arranged between a first pixel row and a second pixel row of the substrate in the first area,
the dummy pixel includes a first dummy pixel and a second dummy pixel arranged in the first non-display area so as to correspond to the first pixel row and the second pixel row, respectively,
each of the first and second dummy pixels includes a dummy pixel circuit and a first capacitor electrically connected to the dummy pixel circuit, and
the first capacitor of the first dummy pixel and the first capacitor of the second dummy pixel have different sizes.

20. The electronic device of claim 19, wherein:
the second dummy pixel is located closer to the first area than the first dummy pixel in the first non-display area, and
the first capacitor of the first dummy pixel has a greater size than the first capacitor of the second dummy pixel.
